(19) United States
(12) Patent Application Publication
(10) Pub. No.: US 2025/0301665 A1
(43) Pub. Date: Sep. 25, 2025

(54) STORAGE DEVICE

(71) Applicant: Kioxia Corporation, Tokyo (JP)

(72) Inventors: Masakazu GOTO, Moriya Ibaraki (JP); Kenta CHOKAWA, Yokohama Kanagawa (JP)

(21) Appl. No.: 18/824,795

(22) Filed: Sep. 4, 2024

(30) Foreign Application Priority Data
Mar. 22, 2024 (JP) 2024-046152

(51) Int. Cl. H10B 63/00; G11C 13/00; H10B 61/00; H10N 50/10; H10N 50/85; H10N 70/00; H10N 70/20

(52) U.S. Cl. CPC H10B 63/80; G11C 13/004; G11C 13/0069; H10B 61/10; H10B 63/20; H10N 50/10; H10N 50/85; H10N 70/24; H10N 70/826; H10N 70/841; H10N 70/8822; H10N 70/8825; H10N 70/8828; H10N 70/8833

(57) ABSTRACT

A storage device includes memory cells each including: a first layer, a second layer, a third layer between the first and second layers, a switching layer between the first and third layers, and a variable resistance layer between the second and third layers. The switching layer includes first and second regions. The first region includes: first and second elements. The second region includes: the first element, a third element, an atomic number of which is greater than that of the second element, and a fourth element. An atomic concentration of a fifth element in the second region is higher than an atomic concentration of the fifth element in the first region. The fifth element is selected from a group consisting of zinc, tin, gallium, indium, bismuth, magnesium, and calcium.

### CROSS-REFERENCE TO RELATED APPLICATIONS

This application is based upon and claims the benefit of priority from Japanese Patent Application No. 2024-046152, filed Mar. 22, 2024, the entire contents of which are incorporated herein by reference.

### FIELD

Embodiments described herein relate generally to a storage device.

### BACKGROUND

As a large-capacity nonvolatile storage device, there is a cross-point-type two-terminal storage device. A cross-point-type two-terminal storage device readily allows miniaturization and high integration of memory cells.

Each memory cell of a cross-point-type two-terminal storage device includes, for example, a variable resistance element and a switching element. Since each memory cell includes the switching element, current flowing through memory cells other than the selected memory cell is suppressed.

The switching element is required to have excellent characteristics such as a low leakage current, a high on-current, and high reliability.

### BRIEF DESCRIPTION OF THE DRAWINGS

FIG. 1 is a schematic diagram of a storage device according to a first embodiment.

FIG. 2 is a cross-sectional view of each memory cell of the storage device according to the first embodiment.

FIG. 3 is a diagram illustrating an operation performed by the storage device according to the first embodiment.

FIG. 4 is a diagram illustrating the current-voltage characteristic of a switching element in the first embodiment.

FIG. 5 is a cross-sectional view of a memory cell of a storage device according to Comparative Example 1.

FIG. 6 is a cross-sectional view of a memory cell of a storage device according to Comparative Example 2.

FIG. 7 is a cross-sectional view of a memory cell of a storage device according to a first variation of the first embodiment.

FIG. 8 is a cross-sectional view of a memory cell of a storage device according to a second variation of the first embodiment.

FIG. 9 is a cross-sectional view of a memory cell of a storage device according to a third variation of the first embodiment.

FIG. 10 is a cross-sectional view of a memory cell of a storage device according to a fourth variation of the first embodiment.

FIG. 11 is a cross-sectional view of each memory cell of a storage device according to a second embodiment.

FIG. 12 is a cross-sectional view of each memory cell of a storage device according to a third embodiment.

FIG. 13 is a cross-sectional view of each memory cell of a storage device according to a fourth embodiment.

FIG. 14 is a diagram illustrating the current-voltage characteristic of a memory element in the fourth embodiment.

FIG. 15 is a diagram illustrating an example of a first memory operation of the storage device according to the fourth embodiment.

FIG. 16 is a diagram illustrating an example of a second memory operation of the storage device according to the fourth embodiment.

FIG. 17 is a diagram illustrating the current-voltage characteristic of a memory element in a first variation of the fourth embodiment.

FIG. 18 is a diagram illustrating an example of a third memory operation of a storage device according to the first variation of the fourth embodiment.

FIG. 19 is a diagram illustrating an example of a fourth memory operation of the storage device according to the first variation of the fourth embodiment.

FIG. 20 is a diagram illustrating the current-voltage characteristic of a memory element in a second variation of the fourth embodiment.

FIG. 21 is a diagram illustrating an example of a fifth memory operation of a storage device according to the second variation of the fourth embodiment.

FIG. 22 is a diagram illustrating an example of a sixth memory operation of the storage device according to the second variation of the fourth embodiment.

FIG. 23 is a diagram illustrating the current-voltage characteristic of a memory element in a third variation of the fourth embodiment.

FIG. 24 is a diagram illustrating an example of a seventh memory operation of a storage device according to the third variation of the fourth embodiment.

FIG. 25 is a diagram illustrating an example of an eighth memory operation of the storage device according to the third variation of the fourth embodiment.

### DETAILED DESCRIPTION

Embodiments of this disclosure provide a storage device including a switching element having excellent characteristics.

In general, according to one embodiment, a storage device comprises a plurality of memory cells each including: a first conductive layer, a second conductive layer, a third conductive layer between the first and second conductive layers, a switching layer between the first and third conductive layers, and a variable resistance layer between the second and third conductive layers. The switching layer includes at least one first region and at least one second region. The first region includes at least: a first element selected from a group consisting of zirconium, yttrium, tantalum, lanthanum, cerium, titanium, hafnium, magnesium, and aluminum, and a second element selected from a group consisting of oxygen, sulfur, and selenium. The second region includes at least: the first element, a third element selected from a group consisting of sulfur, selenium, and tellurium, an atomic number of the third element being greater than an atomic number of the second element, and a fourth element selected from a group consisting of sulfur, selenium, and tellurium, and an atomic concentration of a fifth element in the second region is higher than an atomic concentration of the fifth element in the first region, the fifth element being selected from a group consisting of zinc, tin, gallium, indium, bismuth, magnesium, and calcium.

Embodiments of this disclosure will be described below with reference to the drawings. In the following description, the same members or components are assigned the same reference numerals, and the same descriptions for such members or components will not be repeated.

Qualitative analysis and quantitative analysis of the chemical composition that constitute a storage device in the present specification can be performed, Rutherford backscattering for example, by using spectroscopy (RBS), secondary ion mass spectroscopy (SIMS), energy dispersive X-ray spectroscopy (EDX), or electron energy loss spectroscopy (EELS). Furthermore, a transmission electron microscope (TEM) can, for example, be used to measure the thickness of each member that constitutes the storage device, the distance between the members, and other parameters. In addition, for example, X-ray photoelectron spectroscopy (XPS), X-ray absorption fine structure analysis (XAFS), Raman spectroscopy (Raman), or EELS can be used to identify the constituent substances of the members that constitute the storage device, and measure abundance ratios, bonding states, local structures (e.g., interatomic distances and coordination numbers), and chemical states. Moreover, EELS can, for example, be used to measure the band gap of each of the members that constitute the storage device.

### First Embodiment

A storage device 1 according to a first embodiment includes memory cells each including a first electrically conductive layer, a second electrically conductive layer, a third electrically conductive layer provided between the first and second electrically conductive layers, a switching layer provided between the first and third electrically conductive layers, and a variable resistance layer provided between the third and second electrically conductive layers. The switching layer includes at least one first region and at least one second region having a chemical composition different from the chemical composition of the first region. The first region contains a first substance containing a first element selected from the group consisting of zirconium (Zr), yttrium (Y), tantalum (Ta), lanthanum (La), cerium (Ce), titanium (Ti), hafnium (Hf), magnesium (Mg), and aluminum (Al), and a second element selected from the group consisting of oxygen (O), sulfur(S), and selenium (Se). The second region contains a second substance containing the first element and a third element selected from the group consisting of sulfur(S), selenium (Se), and tellurium (Te) and having an atomic number greater than the atomic number of the second element, and a third substance containing a fifth element selected from the group consisting of zinc (Zn), tin (Sn), gallium (Ga), indium (In), bismuth (Bi), magnesium (Mg), and calcium (Ca) and a fourth element selected from the group consisting of sulfur(S), selenium (Se), and tellurium (Te). The first region contains or does not contain the fifth element, and the atomic concentration of the fifth element in the second region is higher than the atomic concentration of the fifth element in the first region.

The storage device 1 according to the first embodiment further includes a plurality of first wires and a plurality of second wires that intersect with the plurality of first wires. The memory cell described above is provided in a region where one of the plurality of first wires intersects with one of the plurality of second wires.

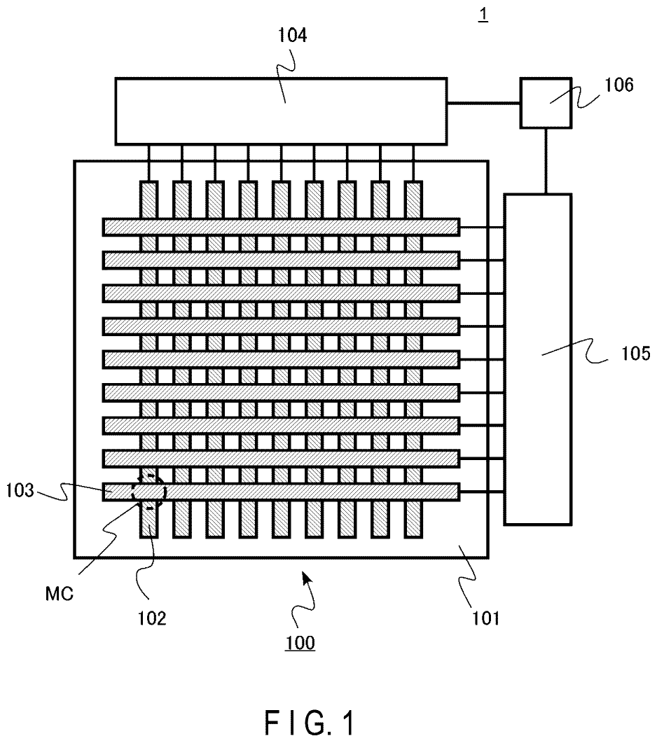

FIG. 1 is a block diagram of the storage device 1 according to the first embodiment.

A memory cell array 100 of the storage device 1 according to the first embodiment includes, for example, a plurality of word lines 102 and a plurality of bit lines 103, which intersect with the word lines 102, on a semiconductor substrate 101 via an insulating layer. The bit lines 103 are provided, for example, in a layer above the word lines 102. A first control circuit 104, a second control circuit 105, and a sense circuit 106 are provided as peripheral circuits around the memory cell array 100.

A plurality of memory cells MC are provided in the regions where the word lines 102 and the bit lines 103 intersect with each other. The storage device 1 according to the first embodiment is a two-terminal magneto-resistive memory having a cross-point structure.

The plurality of word lines 102 are each connected to the first control circuit 104. The plurality of bit lines 103 are each connected to the second control circuit 105. The sense circuit 106 is connected to the first control circuit 104 and the second control circuit 105.

The first control circuit 104 and the second control circuit 105, for example, have the function of selecting a desired memory cell MC, writing data to the memory cell MC, reading the data from the memory cell MC, deleting the data in the memory cell MC, and performing other operations. In the data reading operation, the data in the memory cell MC is read as the amount of current flowing between the word line 102 and the bit line 103 or as a change in potential at the bit line 103. The sense circuit 106 has the function of determining the amount of current or a change in potential to determine the polarity of the data. For example, the sense circuit 106 determines whether the data is “0” or “1”.

The first control circuit 104, the second control circuit 105, and the sense circuit 106 are each formed, for example, of an electronic circuit using a semiconductor device formed on the semiconductor substrate 101.

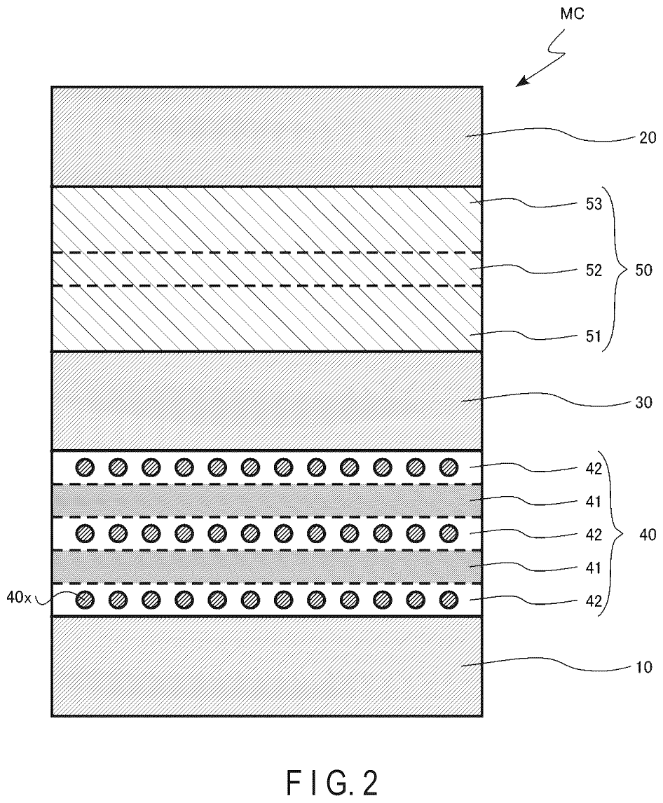

FIG. 2 is a cross-sectional view of each of the memory cells of the storage device 1 according to the first embodiment. FIG. 2 shows a cross section, for example, of one memory cell MC indicated by a dotted circle in the memory cell array 100 in FIG. 1.

The memory cell MC includes a lower electrode 10, an upper electrode 20, an intermediate electrode 30, a switching layer 40, and a variable resistance layer 50, as shown in FIG. 2. The switching layer 40 includes a first region 41, a second region 42, and electric conductors 40x. The variable resistance layer 50 includes a fixed layer 51, a tunnel layer 52, and a free layer 53.

The lower electrode 10, the switching layer 40, and the intermediate electrode 30 constitute a switching element of the memory cell MC. The intermediate electrode 30, the variable resistance layer 50, and the upper electrode 20 constitute a variable resistance element of the memory cell MC.

The lower electrode 10 is connected to the word lines 102. The lower electrode 10 is made, for example, of metal. The lower electrode 10 contains, for example, at least one substance selected from the group consisting of carbon, carbon nitride, tungsten, tungsten carbide, and tungsten nitride. The lower electrode 10 may be part of the word lines 102.

The upper electrode 20 is connected to the bit lines 103. The upper electrode 20 is made, for example, of metal. The upper electrode 20 contains, for example, at least one substance selected from the group consisting of carbon, carbon nitride, tungsten, tungsten carbide, and tungsten nitride. The upper electrode 20 may be part of the bit lines 103.

The intermediate electrode 30 is provided between the lower electrode 10 and the upper electrode 20. The intermediate electrode 30 is made, for example, of metal. The intermediate electrode 30 contains, for example, at least one substance selected from the group consisting of carbon, carbon nitride, tungsten, tungsten carbide, and tungsten nitride.

The switching layer 40 is provided between the lower electrode 10 and the intermediate electrode 30. The thickness of the switching layer 40 in a first direction from the lower electrode 10 toward the upper electrode 20 is, for example, greater than or equal to 5 nm and smaller than or equal to 50 nm. The thickness of the switching layer 40 in the first direction from the lower electrode 10 toward the upper electrode 20 is, for example, more preferably greater than or equal to 5 nm and smaller than or equal to 20 nm.

The switching layer 40 has the function of suppressing an increase in a half-selected leakage current flowing through a half-selected cell. The switching layer 40 has a nonlinear current-voltage characteristic that causes the current to steeply rise at a specific threshold voltage.

The switching layer 40 includes at least one first region 41 and at least one second region 42. The first region 41 and the second region 42 are arranged, for example, alternately in the first direction, as shown in FIG. 2. The first region 41 and the second region 42 are, for example, alternately layered in the first direction. Either the first region 41 or the second region 42 may be provided at the position adjacent to the lower electrode 10. Either the first region 41 or the second region 42 may be provided at the position adjacent to the intermediate electrode 30.

Note that FIG. 2 shows a case where the first region 41 is formed of two layers and the second region 42 is formed of three layers by way of example, and the numbers 41 are not limited to the numbers described above. For example, the first region 41 and the second region 42 may each be a monolayer.

The switching layer 40 includes the first, second, and third substances. The first, second, and third substances are, for example, the primary component of the switching layer 40. The configuration in which the first, second, and third substances are the primary component of the switching layer 40 means that the switching layer 40 does not contain any substance having an abundance ratio higher than that of any of the first, second, and third substances. The abundance ratio is, for example, a molar ratio.

The first region 41 contains the first substance. For example, the first substance is the primary component of the first region 41. The first region 41 contains or does not contain the third substance.

The second region 42 contains the second and third substances. For example, the second and third substances are the primary component of the second region 42.

The first substance contains the first element selected from the group consisting of zirconium (Zr), yttrium (Y), tantalum (Ta), lanthanum (La), cerium (Ce), titanium (Ti), hafnium (Hf), magnesium (Mg), and aluminum (Al), and the second element selected from the group consisting of oxygen (O), sulfur(S), and selenium (Se). The second element is an element that belongs to the sixteenth group.

The first substance is, for example, a compound of the first element and the second element. The first substance is an insulator.

The first substance is, for example, zirconium oxide, yttrium oxide, tantalum oxide, lanthanum oxide, cerium oxide, titanium oxide, hafnium oxide, magnesium oxide, aluminum oxide, zirconium sulfide, yttrium sulfide, tantalum sulfide, lanthanum sulfide, cerium sulfide, titanium sulfide, hafnium sulfide, magnesium sulfide, aluminum sulfide, zirconium selenide, yttrium selenide, tantalum selenide, lanthanum selenide, cerium selenide, titanium selenide, hafnium selenide, magnesium selenide, and aluminum selenide.

The second substance contains the first element contained in the first substance, and the third element selected from the group consisting of sulfur(S), selenium (Se), and tellurium (Te). The third element is an element that belongs to the sixteenth group. The third element differs from the second element contained in the first substance. The atomic number of the third element is greater than the atomic number of the second element contained in the first substance.

The second substance is, for example, a compound of the first element and the third element. The second substance is an insulator.

The second substance is, for example, zirconium sulfide, yttrium sulfide, tantalum sulfide, lanthanum sulfide, cerium sulfide, titanium sulfide, hafnium sulfide, magnesium sulfide, aluminum sulfide, zirconium selenide, yttrium selenide, tantalum selenide, lanthanum selenide, cerium selenide, titanium selenide, hafnium selenide, magnesium selenide, aluminum selenide, zirconium telluride, yttrium telluride, tantalum telluride, lanthanum telluride, cerium telluride, titanium telluride, hafnium telluride, magnesium telluride, or aluminum telluride.

The third substance contains the fifth element selected from the group consisting of zinc (Zn), tin (Sn), gallium (Ga), indium (In), bismuth (Bi), magnesium (Mg), and calcium (Ca), and the fourth element selected from the group consisting of sulfur(S), selenium (Se), and tellurium (Te).

The third substance is, for example, a compound of the fifth element and the fourth element. The third substance is an electric conductor.

The third substance is, for example, zinc sulfide, tin sulfide, gallium sulfide, indium sulfide, bismuth sulfide, magnesium sulfide, calcium sulfide, zinc selenide, tin selenide, gallium selenide, indium selenide, bismuth selenide, magnesium selenide, calcium selenide, zinc telluride, tin telluride, gallium telluride, indium telluride, bismuth telluride, magnesium telluride, or calcium telluride.

The first substance is a first matrix of the switching layer 40. The second substance is a second matrix of the switching layer 40.

The switching layer 40 includes the electric conductors 40x. The electric conductors 40x are contained in the second region 42. The electric conductors 40x are, for example, dispersed in the second matrix of the second region 42. The electric conductors 40x may or may not be contained in the first region 41. The abundance ratio of the electric conductors 40x in the second region 42 is higher than the abundance ratio of the electric conductors 40x in the first region 41. The abundance ratio is, for example, a molar ratio.

Each of the electric conductors 40x contains the third substance. The electric conductor 40x is, for example, the third substance. Each of the electric conductor 40x contains the fourth and fifth elements.

The first region 41 contains or does not contain the fifth element. The atomic concentration of the fifth element in the second region 42 is higher than the atomic concentration of the fifth element in the first region 41. The atomic concentration of the fifth element in the second region 42 is, for example, higher than or equal to ten times and lower than or equal to one hundred times the atomic concentration of the fifth element in the first region 41.

The sum of the atomic concentrations of the first, second, third, fourth, and fifth elements in the switching layer 40 is, for example, greater than or equal to 80% and smaller than or equal to 100%.

The band gap of the second substance is narrower than the band gap of the first substance. The band gap of the first substance contained in the first region 41 and the band gap of the second substance contained in the second region 42 can be measured, for example, by using EELS.

In the case of a compound of a metal element and an element that belongs to the sixteenth group, the greater the atomic number of the element that belongs to the sixteenth group in the compound, the narrower the band gap of the compound. For example, when the metal element is zirconium (Zr), the band gap of zirconium sulfide is narrower than the band gap of zirconium oxide. The band gap of zirconium selenide is narrower than the band gap of zirconium sulfide. The band gap of zirconium telluride is narrower than the band gap of zirconium selenide.

The atomic number of the third element, which is an element that belongs to the sixteenth group and is contained in the second substance, is greater than the atomic number of the second element, which is an element that belongs to the sixteenth group and is contained in the first substance. Therefore, when the first and second substances are each a compound containing an element that belongs to the sixteenth group, the band gap of the second substance is narrower than the band gap of the first substance.

Furthermore, the amount of charge of the third substance in the case where the third substance is present in the first substance is greater than the amount of charge of the third substance in the case where the third substance is present in the second substance. It is believed that the amount of charge of the third substance increases as the band gap of the matrix increases. In other words, it is believed that narrowing the bandgap of the matrix allows reduction in the amount of charge of the third substance. Note that the amount of charge of the third substance can be calculated, for example, by first-principles calculation.

The switching layer 40 can be formed, for example, by sputtering. For example, the first region 41 is formed by sputtering using a target made of the first substance. Furthermore, for example, the second region 42 can be formed by co-sputtering using a target made of the second substance and a target made of the third substance. The second region 42 can instead be formed, for example, by sputtering using a target made of a mixture of the second substance and the third substance.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed of the fixed layer 51, the tunnel layer 52, and the free layer 53.

The variable resistance layer 50 has the function of storing data in the form of a change in the resistance thereof. The variable resistance layer 50 is characterized, for example, in that application of a predetermined voltage to the variable resistance layer 50 changes the electrical resistance thereof.

The fixed layer 51 is made of a ferromagnetic. In the fixed layer 51, a predetermined write voltage applied thereto does not change the magnetization direction, but the magnetization direction is fixed in a specific direction.

The tunnel layer 52 is an insulator. The tunnel effect causes electrons to pass through the tunnel layer 52.

The free layer 53 is made of a ferromagnetic. In the free layer 53, the predetermined write voltage applied thereto changes the magnetization direction. The magnetization direction of the free layer 53 can be either parallel to the magnetization direction of the fixed layer 51 or antiparallel to the magnetization direction of the fixed layer 51. For example, applying a voltage to the space between the intermediate electrode 30 and the upper electrode 20 to cause a current to flow through the space allows a change in the magnetization direction of the free layer 53.

Changing the magnetization direction of the free layer 53 changes the electrical resistance of the variable resistance layer 50. When the magnetization direction of the free layer 53 is antiparallel to the magnetization direction of the fixed layer 51, a high resistance state in which the current is unlikely to flow occurs. On the other hand, when the magnetization direction of the free layer 53 is parallel to the magnetization direction of the fixed layer 51, a low resistance state in which the current is likely to flow occurs. Note that the arrangement of the fixed layer 51 and the free layer 53 may be reversed. That is, the intermediate electrode 30, the free layer 53, the tunnel layer 52, the fixed layer 51, and the upper electrode 20 may be layered in this order.

The effects and advantages of the storage device 1 according to the first embodiment will next be described.

In the storage device 1 according to the first embodiment, changing the magnetization direction of the free layer 53 changes the resistance of the variable resistance layer 50, as described above. When the magnetization direction of the free layer 53 is antiparallel to the magnetization direction of the fixed layer 51, the high resistance state, in which the current is unlikely to flow, occurs. On the other hand, when the magnetization direction of the free layer 53 is parallel to the magnetization direction of the fixed layer 51, the low resistance state, in which the current is likely to flow, occurs.

For example, the high resistance state of the variable resistance layer 50 is defined as data “1”, and the low resistance state is defined as data “0”. The memory cells MC can each maintain the different resistance states and therefore store 1-bit data, “0” and “1”. Writing data to one memory cell MC is performed by applying a voltage to the region where the bit line 103 and the word line 102 connected to the memory cell MC intersect with each other to cause a current to flow through the region.

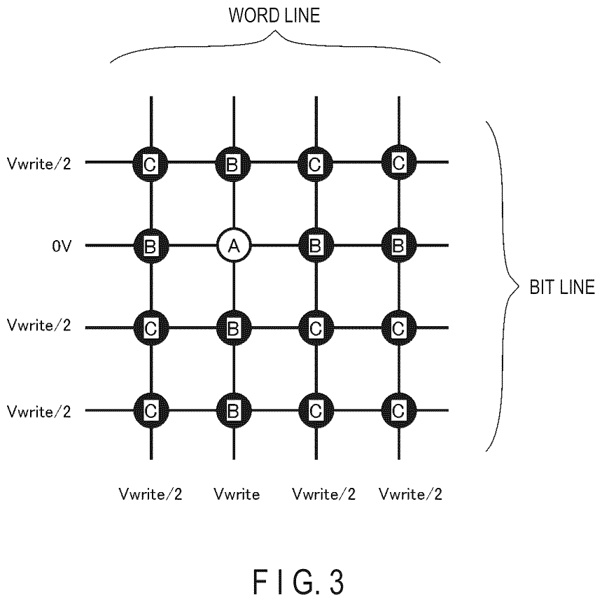

FIG. 3 is a diagram illustrating an operation performed by the storage device 1 according to the first embodiment. FIG. 3 relates to a case where one memory cell MC in the memory cell array is selected for a write operation and shows the voltage applied to the memory cell MC. The intersection of a word line and a bit line represents each memory cell MC.

The selected memory cell MC is a memory cell A. A write voltage Vwrite is applied to the word line connected to the memory cell A. Furthermore, 0 V is applied to the bit line connected to the memory cell A.

The following description will be made with reference to a case where a voltage (Vwrite/2), which is half the write voltage, is applied to the word lines and the bit lines that are not connected to the memory cell A.

The voltage applied to memory cells C (i.e., non-selected cells) connected to the word lines and the bit lines that are not connected to the memory cell A is 0 V. That is, no voltage is applied to the memory cells C.

On the other hand, the voltage (Vwrite/2), which is half the write voltage Vwrite, is applied to memory cells B (i.e., half-selected cells) connected to the word line or the bit line connected to the memory cell A. A half-selected leakage current therefore flows through the memory cells B.

Note that an application method other than the method described above may instead be used, that is, the voltage (Vwrite/2), which is half the write voltage, may be applied to the word line connected to the memory cell A, a negative voltage (−Vwrite/2), which is half the write voltage, may be applied to the bit line connected to the memory cell A, and 0 V may be applied to the word lines and the bit lines that are not connected to the memory cell A.

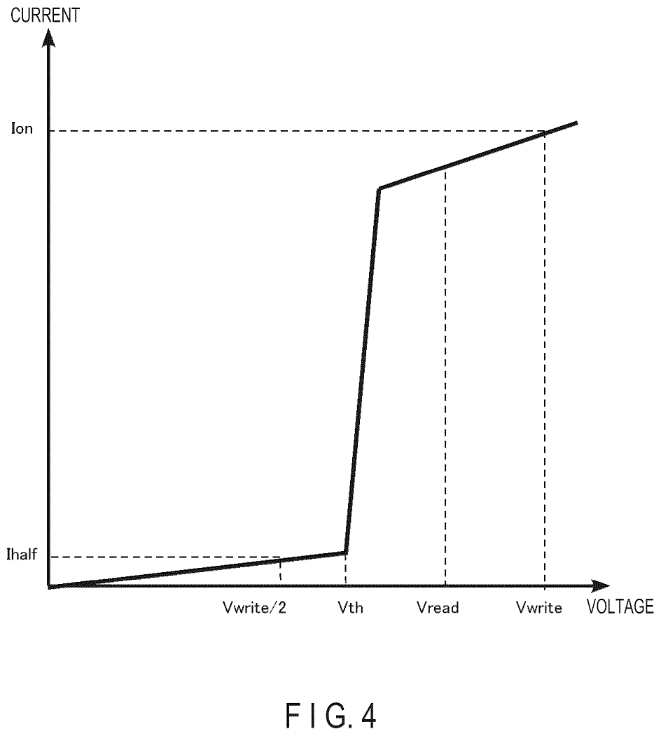

FIG. 4 is a diagram illustrating the current-voltage characteristic of the switching element in the first embodiment. In FIG. 4, the horizontal axis represents the voltage applied to the switching element, and the vertical axis represents the current flowing through the switching element.

The switching element has a nonlinear current-voltage characteristic that causes the current to steeply rise at a threshold voltage Vth. The threshold voltage Vth is, for example, higher than or equal to 0.5 V and lower than or equal to 3 V.

The write voltage Vwrite is so set that the write voltage Vwrite is higher than the threshold voltage Vth, and the voltage (Vwrite/2), which is half the write voltage Vwrite, is lower than the threshold voltage. The current flowing through the switching element when the write voltage Vwrite is applied is an on-current (Ion in FIG. 4). The current flowing through the switching element when the voltage (Vwrite/2), which is half the write voltage Vwrite, is applied is a half-selected leakage current (Ihalf in FIG. 4).

Note that a read voltage Vread, at which data is read from a memory cell MC, is set at a voltage higher than the threshold voltage Vth and lower than the write voltage Vwrite, for example, as shown in FIG. 4. Therefore, when data is read from a memory cell MC, the half-selected leakage current flowing through the half-select cells can also be suppressed.

When the half-select leakage current is large, for example, the power consumed by the chip increases. Furthermore, for example, a voltage drop that occurs in the wiring increases so that a sufficiently high voltage is not applied to a selected cell, resulting in an unstable write operation to the memory cell MC. Moreover, when the on-current is small, for example, an insufficient current flows through the selected cell, resulting in insufficient writing to the memory cell MC. The current-voltage characteristic of the switching element is therefore required to provide both a low half-selected leakage current and a high on-current.

Furthermore, the current-voltage characteristic of the switching element is also required to be highly reliable. That is, it is required to suppress characteristic fluctuations such as half-selected leakage current fluctuations and on-current fluctuations that occur when data is repeatedly written to a memory cell MC to achieve high reliability.

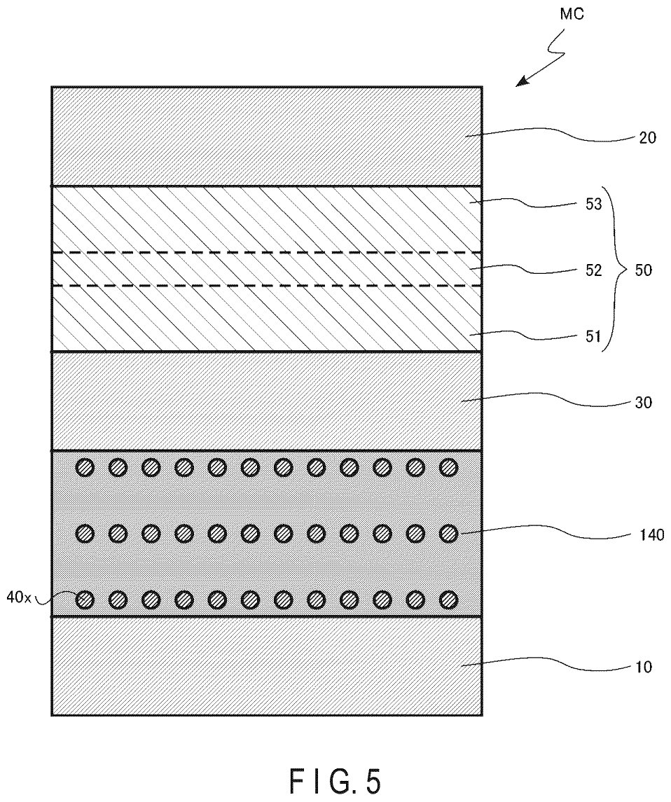

FIG. 5 is a cross-sectional view of each memory cell of a storage device according to Comparative Example 1. FIG. 5 is a diagram corresponding to FIG. 2 in the first embodiment.

The memory cells MC in Comparative Example 1 each include a lower electrode 10, an upper electrode 20, an intermediate electrode 30, a switching layer 140, and a variable resistance layer 50, as shown in FIG. 5. The switching layer 140 includes electric conductors 40x. The variable resistance layer 50 includes a fixed layer 51, a tunnel layer 52, and a free layer 53.

The memory cells MC of the storage device according to Comparative Example 1 differ from the memory cells MC in the first embodiment in that the switching layer 140 does not contain the second substance. In the switching layer 140 of each of the memory cells MC of the storage device according to Comparative Example 1, the electric conductors 40x, which are the third substance, are dispersed in the first matrix, which is the first substance.

In the storage device according to Comparative Example 1, a large characteristic fluctuation occurs when data is repeatedly written to a memory cell MC. It is believed that the characteristic fluctuation of the storage device according to Comparative Example 1 is caused by movement and aggregation of the electric conductors 40x in the switching layer 140. That is, it is believed that the aggregation of the electric conductors 40x forms a leakage current path between the lower electrode 10 and the intermediate electrode 30.

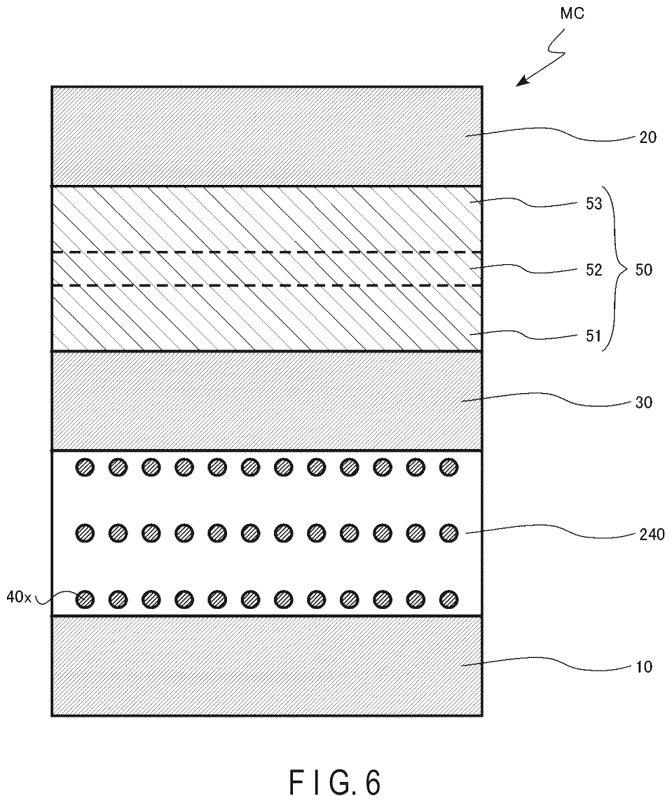

FIG. 6 is a cross-sectional view of each memory cell of a storage device according to Comparative Example 2. FIG. 6 is a diagram corresponding to FIG. 2 in the first embodiment.

The memory cells MC in Comparative Example 2 each include a lower electrode 10, an upper electrode 20, an intermediate electrode 30, a switching layer 240, and a variable resistance layer 50, as shown in FIG. 6. The switching layer 240 includes electric conductors 40x. The variable resistance layer 50 includes a fixed layer 51, a tunnel layer 52, and a free layer 53.

The memory cells MC of the storage device according to Comparative Example 2 differ from the memory cells MC in the first embodiment in that the switching layer 240 does not contain the first substance. In the switching layer 240 of each of the memory cells MC of the storage device according to Comparative Example 2, the electric conductors 40x, which are the third substance, are dispersed in the second matrix, which is the second substance.

In the storage device according to Comparative Example 2, the characteristic fluctuation that occurs when data is repeatedly written to a memory cells MC is suppressed as compared with the fluctuation that occurs in the storage device according to Comparative Example 1. It is believed that the fluctuation of the characteristic of the storage device according to Comparative Example 2 is suppressed because the movement of the electric conductors 40x in the switching layer 240 is suppressed.

The amount of charge of the third substance in the case where the third substance is present in the first substance is greater than the amount of charge of the third substance in the case where the third substance is present in the second substance. In other words, the amount of charge of the third substance in the case where the third substance is present in the second substance is smaller than the amount of charge of the third substance in the case where the third substance is present in the first substance.

In the storage device according to Comparative Example 2, in which the amount of charge of the third substance is small, it is believed that the movement of the third substance due to the electric field is suppressed when a voltage is applied to the space between the lower electrode 10 and the intermediate electrode 30. In other words, it is believed that the movement of the electric conductors 40x in the switching layer 240 is suppressed. It is therefore believed that the aggregation of the electric conductors 40x is suppressed and the formation of the leakage current path between the lower electrode 10 and the intermediate electrode 30 is therefore suppressed.

On the other hand, the second substance has a band gap narrower than the band gap of the first substance. Therefore, in the storage device according to Comparative Example 2, the half-selected leakage current increases as compared with that in the storage device according to Comparative Example 1. The storage device according to Comparative Example 2 therefore has problems, for example, an increase in the power consumed by the chip and the unstable write operation to any of the memory cells MC, as compared with the storage device according to Comparative Example 1.

In the storage device 1 according to the first embodiment, the switching layer 40 includes the first region 41 containing the first substance and the second region 42 containing the second substance. The electric conductors 40x are contained in the second region 42 containing the second substance.

In the storage device 1 according to the first embodiment, the movement and aggregation of the electric conductors 40x are suppressed by the second region 42, where the amount of charge of the electric conductors 40x is small. Furthermore, the first region 41 having a wide band gap reduces the half-selected leakage current. A switching element having high reliability and a small half-selected leakage current can therefore be realized.

### (First Variation)

A storage device 1 according to a first variation of the first embodiment differs from the storage device 1 according to the first embodiment in that the first electrically conductive layer includes a first section and a second section, and the first section contains at least one element selected from hafnium (Hf), aluminum (Al), magnesium (Mg), zirconium (Zr), and titanium (Ti).

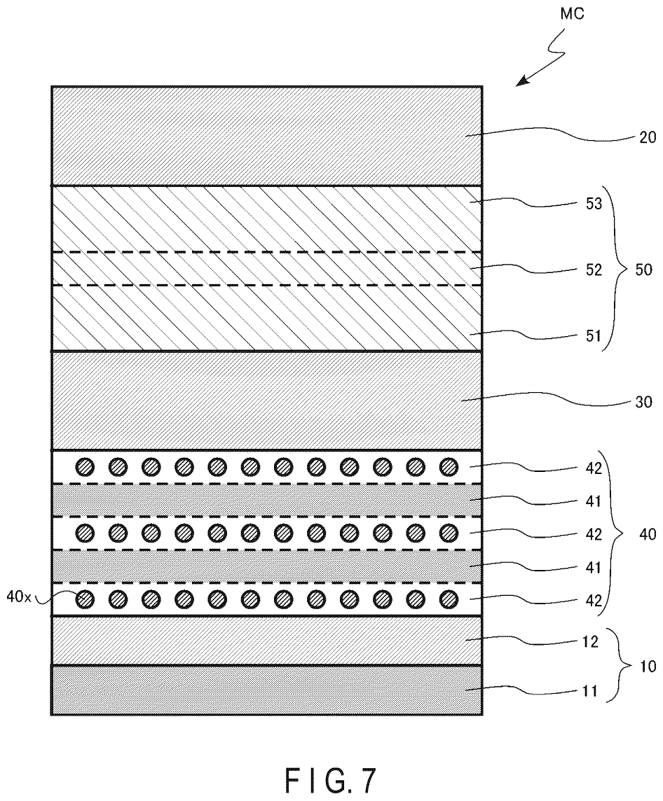

FIG. 7 is a cross-sectional view of each memory cell of the storage device 1 according to the first variation of the first embodiment. FIG. 7 is a diagram corresponding to FIG. 2 in the first embodiment.

The lower electrode 10 of each memory cell of the storage device 1 according to the first variation includes a first section 11 and a second section 12. The second section 12 is provided between the first section 11 and the switching layer 40.

The first section 11 contains at least one element selected from hafnium (Hf), aluminum (Al), magnesium (Mg), zirconium (Zr), and titanium (Ti). The first section 11 contains, for example, a boride of any of the elements described above. The first section 11 contains, for example, at least one substance selected from the group consisting of hafnium, hafnium boride, aluminum magnesium boride, zirconium, zirconium boride, and titanium boride.

The second section 12 contains, for example, at least one substance selected from the group consisting of carbon, carbon nitride, tungsten, tungsten carbide, and tungsten nitride.

In the storage device 1 according to the first variation of the first embodiment, the first section 11 of the lower electrode 10 contains at least one element selected from hafnium (Hf), aluminum (Al), magnesium (Mg), zirconium (Zr), and titanium (Ti) to suppress deterioration of the characteristics of the variable resistance element. Furthermore, since the first section 11 is not in contact with the switching layer 40, desorption of oxygen (O) from the switching layer 40 is suppressed, so that deterioration of the characteristics of the switching element is suppressed.

As described above, according to the first variation of the first embodiment, a switching element having high reliability and a small half-selected leakage current can be realized, as in the first embodiment.

### (Second Variation)

A storage device 1 according to a second variation of the first embodiment differs from the storage device 1 according to the first embodiment in that the first electrically conductive layer includes a first section and a second section, that the first section contains at least one element selected from hafnium (Hf), aluminum (Al), magnesium (Mg), zirconium (Zr), and titanium (Ti), that the second electrically conductive layer contains one element selected from hafnium (Hf), aluminum (Al), magnesium (Mg), zirconium (Zr), and titanium (Ti), that the third electrically conductive layer includes a third section and a fourth section, and that the fourth section contains at least one element selected from hafnium (Hf), aluminum (Al), magnesium (Mg), zirconium (Zr), and titanium (Ti).

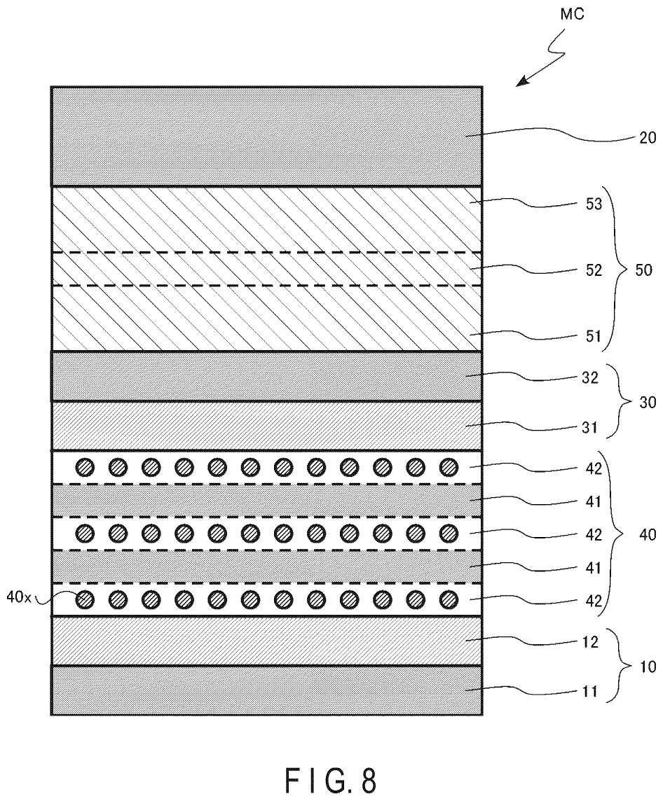

FIG. 8 is a cross-sectional view of each memory cell of the storage device 1 according to the second variation of the first embodiment. FIG. 8 is a diagram corresponding to FIG. 2 in the first embodiment.

The lower electrode 10 of each memory cell of the storage device 1 according to the second variation includes a first section 11 and a second section 12. The second section 12 is provided between the first section 11 and a switching layer 40.

The first section 11 contains at least one element selected from hafnium (Hf), aluminum (Al), magnesium (Mg), zirconium (Zr), and titanium (Ti). The first section 11 contains, for example, a boride of any of the elements described above. The first section 11 contains, for example, at least one substance selected from the group consisting of hafnium, hafnium boride, aluminum magnesium boride, zirconium, zirconium boride, and titanium boride.

The second section 12 contains, for example, at least one substance selected from the group consisting of carbon, carbon nitride, tungsten, tungsten carbide, and tungsten nitride.

The upper electrode 20 of each memory cell of the storage device 1 according to the second variation contains at least one element selected from hafnium (Hf), aluminum (Al), magnesium (Mg), zirconium (Zr), and titanium (Ti). The upper electrode 20 contains, for example, a boride of any of the elements described above. The upper electrode 20 contains, for example, at least one substance selected from the group consisting of hafnium, hafnium boride, aluminum magnesium boride, zirconium, zirconium boride, and titanium boride.

The intermediate electrode 30 of each memory cell of the storage device 1 according to the second variation includes a third section 31 and a fourth section 32. The third section 31 is provided between the fourth section 32 and the switching layer 40.

The third section 31 contains, for example, at least one substance selected from the group consisting of carbon, carbon nitride, tungsten, tungsten carbide, and tungsten nitride.

The fourth section 32 contains at least one element selected from hafnium (Hf), aluminum (Al), magnesium (Mg), zirconium (Zr), and titanium (Ti). The fourth section 32 contains, for example, a boride of any of the elements described above. The fourth section 32 contains, for example, at least one substance selected from the group consisting of hafnium, hafnium boride, aluminum magnesium boride, zirconium, zirconium boride, and titanium boride.

In the storage device 1 according to the second variation of the first embodiment, the first section 11 of the lower electrode 10, the upper electrode 20, and the fourth section 32 of the intermediate electrode 30 contain at least one element selected from hafnium (Hf), aluminum (Al), magnesium (Mg), zirconium (Zr), and titanium (Ti) deterioration of the to suppress characteristics of the variable resistance element. Furthermore, since the first section 11 of the lower electrode 10, the upper electrode 20, and the fourth section 32 of the intermediate electrode 30 are not in contact with the switching layer 40, desorption of oxygen (O) from the switching layer 40 is suppressed, so that deterioration of the characteristics of the switching element is suppressed.

As described above, according to the second variation of the first embodiment, a switching element having high reliability and a small half-selected leakage current can be realized, as in the first embodiment.

### (Third Variation)

A storage device 1 according to a third variation of the first embodiment differs from the storage device 1 according to the first embodiment in that the first electrically conductive layer includes a first section, a second section, and a fifth section, that the first section contains at least one element selected from hafnium (Hf), aluminum (Al), magnesium (Mg), zirconium (Zr), and titanium (Ti), that the second electrically conductive layer contains at least one element selected from hafnium (Hf), aluminum (Al), magnesium (Mg), zirconium (Zr), and titanium (Ti), that the third electrically conductive layer includes a third section and a fourth section, and that the fourth section contains at least one element selected from hafnium (Hf), aluminum (Al), magnesium (Mg), zirconium (Zr), and titanium (Ti).

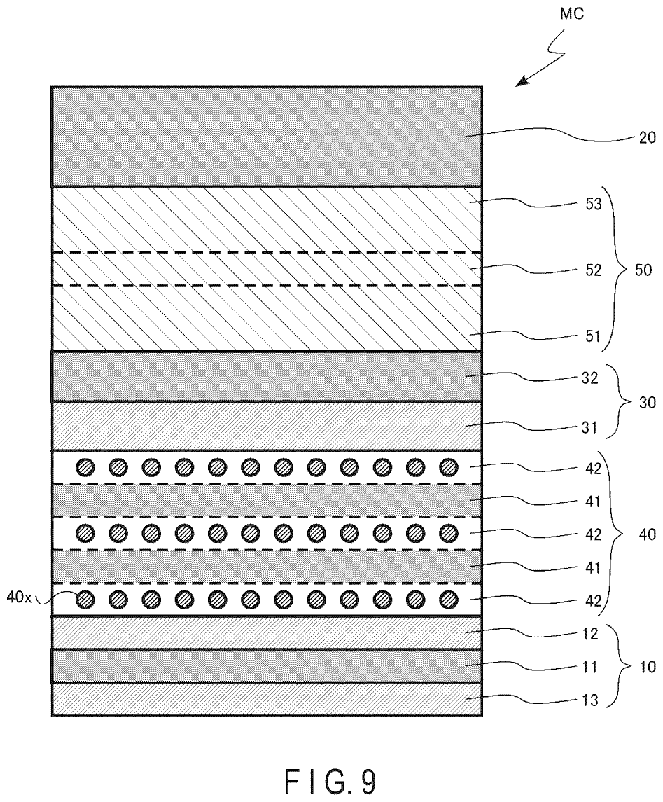

FIG. 9 is a cross-sectional view of each of the memory cells of the storage device 1 according to the third variation of the first embodiment. FIG. 9 is a diagram corresponding to FIG. 2 in the first embodiment.

The lower electrode 10 of each of the memory cells of the storage device 1 according to the third variation includes a first section 11, a second section 12, and a fifth section 13. The second section 12 is provided between the first section 11 and a switching layer 40. The first section 11 is provided between the fifth section 13 and the second section 12.

The first section 11 contains at least one element selected from hafnium (Hf), aluminum (Al), magnesium (Mg), zirconium (Zr), and titanium (Ti). The first section 11 contains, for example, a boride of any of the elements described above. The first section 11 contains, for example, at least one substance selected from the group consisting of hafnium, hafnium boride, aluminum magnesium boride, zirconium, zirconium boride, and titanium boride.

The second section 12 and the fifth section 13 contain, for example, at least one substance selected from the group consisting of carbon, carbon nitride, tungsten, tungsten carbide, and tungsten nitride.

The upper electrode 20 of each of the memory cells of the storage device 1 according to the third variation contains at least one element selected from hafnium (Hf), aluminum (Al), magnesium (Mg), zirconium (Zr), and titanium (Ti). The upper electrode 20 contains, for example, a boride of any of the elements described above. The upper electrode 20 contains, for example, at least one substance selected from the group consisting of hafnium, hafnium boride, aluminum magnesium boride, zirconium, zirconium boride, and titanium boride.

The intermediate electrode 30 of each of the memory cells of the storage device 1 according to the third variation includes the third section 31 and the fourth section 32. The third section 31 is provided between the fourth section 32 and the switching layer 40.

The third section 31 contains, for example, at least one substance selected from the group consisting of carbon, carbon nitride, tungsten, tungsten carbide, and tungsten nitride.

The fourth section 32 of each of the memory cells of the storage device 1 according to the third variation contains at least one element selected from hafnium (Hf), aluminum (Al), magnesium (Mg), zirconium (Zr), and titanium (Ti). The fourth section 32 contains, for example, a boride of any of the elements described above. The fourth section 32 contains, for example, at least one substance selected from the group consisting of hafnium, hafnium boride, aluminum magnesium boride, zirconium, zirconium boride, and titanium boride.

In the storage device 1 according to the third variation of the first embodiment, the first section 11 of the lower electrode 10, the upper electrode 20, and the fourth section 32 of the intermediate electrode 30 contain at least one element selected from hafnium (Hf), aluminum (Al), magnesium (Mg), zirconium (Zr), and titanium (Ti) suppress deterioration of the to characteristics of the variable resistance element. Furthermore, since the first section 11 of the lower electrode 10, the upper electrode 20, and the fourth section 32 of the intermediate electrode 30 is not in contact with the switching layer 40, desorption of oxygen (O) from the switching layer 40 is suppressed, so that deterioration of the characteristics of the switching element is suppressed.

As described above, according to the third variation of the first embodiment, a switching element having high reliability and a small half-selected leakage current can be realized, as in the first embodiment.

### (Fourth Variation)

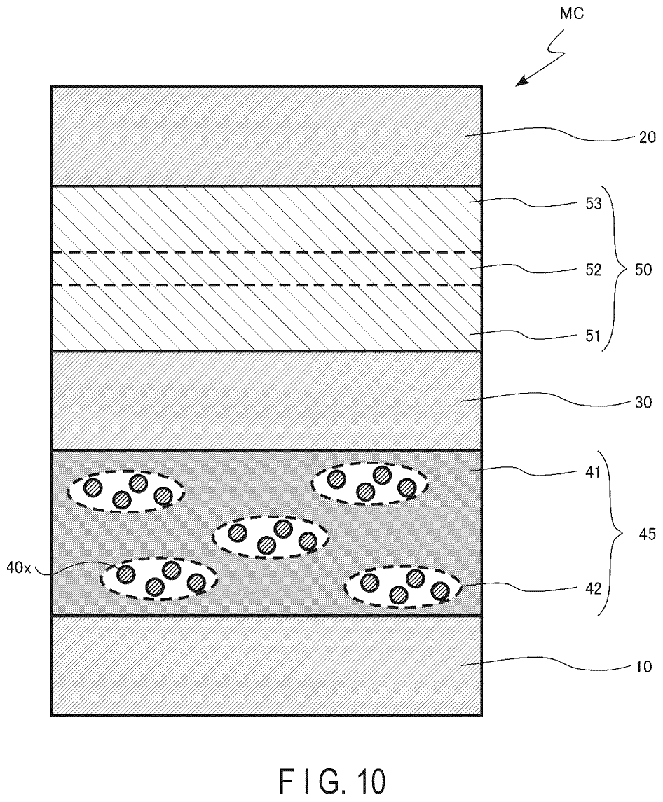

FIG. 10 is a cross-sectional view of each memory cell of a storage device 1 according to a fourth variation of the first embodiment. FIG. 10 is a diagram corresponding to FIG. 2 in the first embodiment.

The memory cells MC in the fourth variation of the first embodiment each include a lower electrode 10, an upper electrode 20, an intermediate electrode 30, a switching layer 45, and a variable resistance layer 50, as shown in FIG. 10. The switching layer 45 includes electric conductors 40x. The variable resistance layer 50 includes a fixed layer 51, a tunnel layer 52, and a free layer 53.

The memory cells MC in the fourth variation differ from the memory cells MC in the first embodiment in that the second region 42 in the switching layer 45 is dispersed in the first region 41. The second region 42 is, for example, surrounded by the first region 41.

According to the fourth variation of the first embodiment, a switching element having high reliability and a small half-selected leakage current can be realized, as in the first embodiment.

According to the first embodiment and the variations thereof, a switching element having excellent characteristics, such as high reliability and a small half-select leakage current, can be realized. The first embodiment and the variations thereof can therefore realize a storage device including a switching element having excellent characteristics.

### Second Embodiment

A storage device 1 according to a second embodiment includes memory cells each including a first electrically conductive layer, a second d electrically conductive layer, a third electrically conductive layer provided between the first and second electrically conductive layers, a switching layer provided between the first and third electrically conductive layers, and a variable resistance layer provided between the third and second electrically conductive layers. The switching layer includes at least one first region containing a first substance and at least one second region containing second and third substances and having a chemical composition different from the chemical composition of the first region. The third substance contains zinc (Zn) and one element selected from the group consisting of sulfur(S), selenium (Se), and tellurium (Te). The combination of the first and second substances is a first combination in which the first substance contains silicon (Si) and oxygen (O), and the second substance contains oxygen (O) and one element selected from the group consisting of zirconium (Zr), hafnium (Hf), titanium (Ti), and aluminum (Al), a second combination in which the first substance contains silicon (Si) and oxygen (O), and the second substance contains nitrogen (N) and one element selected from the group consisting of silicon (Si), aluminum (Al), and gallium (Ga), a third combination in which the first substance contains silicon (Si) and nitrogen (N), and the second substance contains oxygen (O) and one element selected from the group consisting of zirconium (Zr), hafnium (Hf), titanium (Ti), and aluminum (Al), a fourth combination in which the first substance contains silicon (Si) and nitrogen (N), and the second substance contains aluminum (Al) and nitrogen (N), a fifth combination in which the first substance contains aluminum (Al) and nitrogen (N), and the second substance contains oxygen (O) and one element selected from the group consisting of zirconium (Zr) and hafnium (Hf), or a sixth combination in which the first substance contains zirconium (Zr) and oxygen (O), and the second substance contains hafnium (Hf) and oxygen (O). The first region contains or does not contain zinc (Zn), and the atomic concentration of zinc (Zn) in the second region is higher than the atomic concentration of zinc (Zn) in the first region.

The storage device 1 according to the second embodiment differs from the storage device 1 according to the first embodiment in terms of the combination of the first and second substances. In the following sections, some descriptions that duplicate the contents of the first embodiment may be omitted.

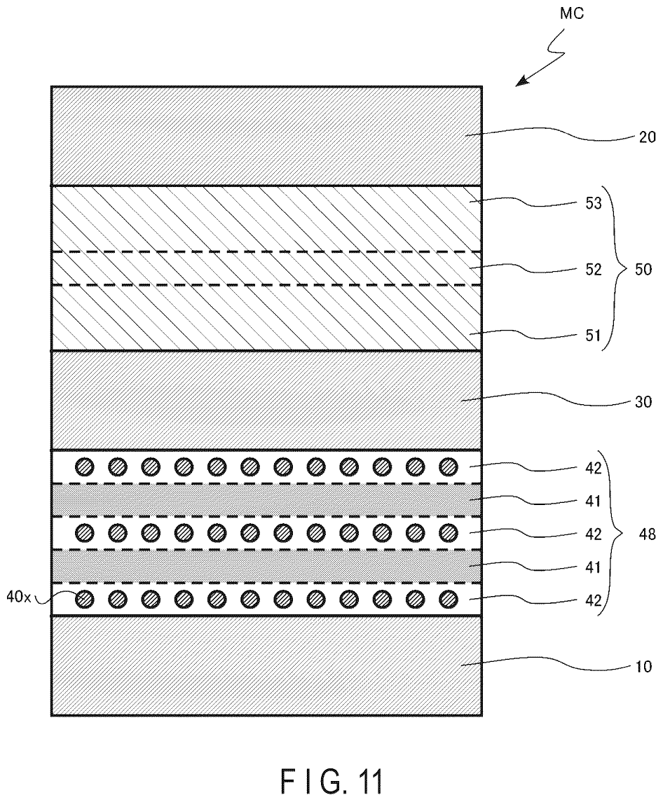

FIG. 11 is a cross-sectional view of each memory cell of the storage device 1 according to the second embodiment. FIG. 11 is a diagram corresponding to FIG. 2 in the first embodiment.

The memory cells MC according to the second embodiment each include a lower electrode 10, an upper electrode 20, an intermediate electrode 30, a switching layer 48, and variable resistance layer 50, as shown in FIG. 11. The switching layer 48 includes a first region 41, a second region 42, and electric conductors 40x. The variable resistance layer 50 includes a fixed layer 51, a tunnel layer 52, and a free layer 53.

The switching layer 48 includes at least one first region 41 and at least one second region 42. The first region 41 and the second region 42 are arranged, for example, alternately in the first direction, as shown in FIG. 11.

The switching layer 48 includes a first substance, a second substance, and a third substance. The first, second, and third substances are the primary component of the switching layer 48.

The first region 41 contains the first substance. The second region 42 contains the second and third substances.

The combination of the first and second substances of the switching layer 48 is a combination selected from the group consisting of a first combination, a second combination, a third combination, a fourth combination, a fifth combination, and sixth combination described below.

The first combination is a combination in which the first substance contains silicon (Si) and oxygen (O), and the second substance contains oxygen (O) and one element selected from the group consisting of zirconium (Zr), hafnium (Hf), titanium (Ti), and aluminum (Al). The first substance is, for example, silicon oxide. The second substance e is, for example, zirconium oxide, hafnium oxide, titanium oxide, or aluminum oxide.

The second combination is a combination in which the first t substance contains silicon (Si) and oxygen (O), and the second substance contains nitrogen (N) and one element selected from the group consisting of silicon (Si), aluminum (Al), and gallium (Ga). The first substance is, for example, silicon oxide. The second substance is, for example, silicon nitride, aluminum nitride, or gallium nitride.

The third combination is a combination in which the first substance contains silicon (Si) and nitrogen (N), and the second substance contains oxygen (O) and one element selected from the group consisting of zirconium (Zr), hafnium (Hf), titanium (Ti), and aluminum (Al). The first substance is, for example, silicon nitride. The second substance is, for example, zirconium oxide, hafnium oxide, titanium oxide, or aluminum oxide.

The fourth combination is a combination in which the first substance contains silicon (Si) and nitrogen (N), and the second substance contains aluminum (Al) and nitrogen (N). The first substance is, for example, silicon nitride. The second substance is, for example, aluminum nitride.

The fifth combination is a combination in which the first substance contains aluminum (Al) and nitrogen (N), and the second substance contains oxygen (O) and one element selected from the group consisting of zirconium (Zr) and hafnium (Hf). The first substance is, for example, aluminum nitride. The second substance is, for example, zirconium oxide or hafnium oxide.

The sixth combination is a combination in which the first substance contains zirconium (Zr) and oxygen (O), and the second substance contains hafnium (Hf) and oxygen (O). The first substance is, for example, zirconium oxide. The second substance is, for example, hafnium oxide.

The first substance contains oxygen (O) or nitrogen (N). The first substance is, for example, an oxide or a nitride.

The second substance contains oxygen (O) or nitrogen (N). The second substance is, for example, an oxide or a nitride.

The third substance contains zinc (Zn) and one element selected from the group consisting of sulfur(S), selenium (Se), and tellurium (Te).

The third substance is an electric conductor. The third substance is, for example, zinc sulfide, zinc selenide, or zinc telluride.

The first substance is a first matrix of the switching layer 40. The second substance is a second matrix of the switching layer 40.

The switching layer 40 includes the electric conductors 40x. The electric conductors 40x are contained in the second region 42. The electric conductors 40x are, for example, dispersed in the second matrix of the second region 42. The electric conductors 40x may or may not be contained in the first region 41. The abundance ratio of the electric conductors 40x in the second region 42 is higher than the abundance ratio of the electric conductors 40x in the first region 41. The abundance ratio is, for example, a molar ratio.

Each of the electric conductors 40x contains the third substance. Each of the electric conductors 40x is, for example, the third substance. Each electric conductor 40x is, for example, zinc sulfide, zinc selenide, or zinc telluride.

The first region 41 contains or does not contain zinc (Zn). The atomic concentration of zinc (Zn) in the second region 42 is higher than the atomic concentration of zinc (Zn) in the first region 41. The atomic concentration of zinc (Zn) in the second region 42 is, for example, higher than or equal to ten times and lower than or equal to one hundred times the atomic concentration of zinc (Zn) in the first region 41.

In the switching layer 40, the sum of the atomic concentrations of the first element, the second element, the third element, zinc (Zn), and one element selected from the group consisting of sulfur(S), selenium (Se), and tellurium (Te) is, for example, greater than or equal to 80% and smaller than or equal to 100%.

The band gap of the second substance is narrower than the band gap of the first substance. The band gap of the first substance contained in the first region 41 and the band gap of the second substance contained in the second region 42 can be measured, for example, by using EELS.

Furthermore, the amount of charge of the third substance in the case where the third substance is present in the first substance is greater than the amount of charge of the third substance in the case where the third substance is present in the second substance. The amount of charge of the third substance can be calculated, for example, by first-principles calculation.

According to the second embodiment, a switching element having excellent characteristics, such as high reliability and a small half-select leakage current, can be realized, as in the first embodiment. The second embodiment can therefore realize a storage device including a switching element having excellent characteristics.

### Third Embodiment

A storage device 1 according to a third embodiment differs from the storage device 1 according to the first embodiment in that the storage device 1 is a resistive memory (ReRAM). In the following sections, some descriptions that duplicate the contents of the first embodiment are omitted.

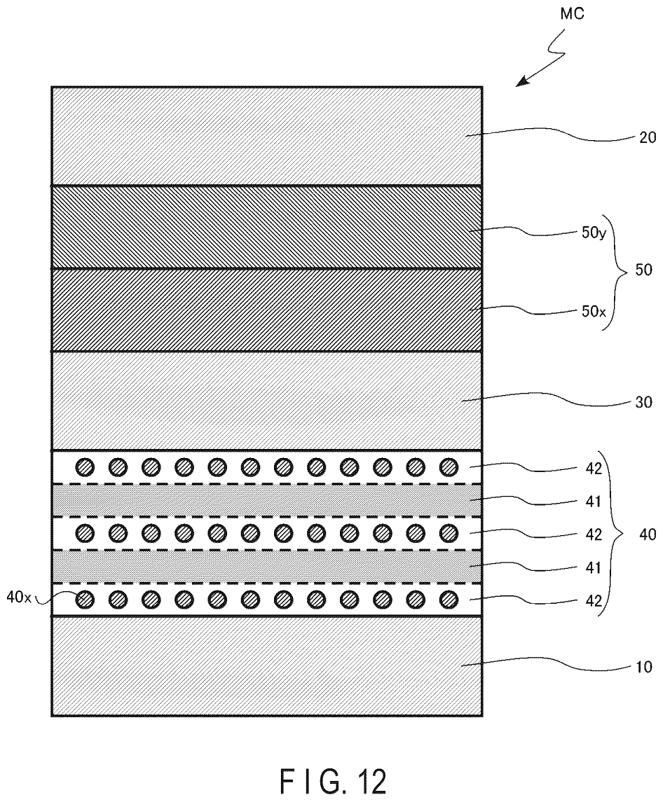

FIG. 12 is a cross-sectional view of each memory cell MC of the storage device 1 according to the third embodiment. FIG. 12 shows a cross section, for example, of one memory cell MC indicated by the dotted circle in the memory cell array 100 in FIG. 1.

Each memory cell MC of the storage device 1 according to the third embodiment includes a lower electrode 10, an upper electrode 20, an intermediate electrode 30, a switching layer 40, and a variable resistance layer 50, as shown in FIG. 12. The variable resistance layer 50 includes a high resistance layer 50x and a low resistance layer 50y.

The lower electrode 10, the switching layer 40, and the intermediate electrode 30 constitute a switching element of the memory cell MC. The intermediate electrode 30, the variable resistance layer 50, and the upper electrode 20 constitute a variable resistance element of the memory cell MC.

The configuration of the switching layer 40 is the same as that in the storage device 1 according to the first embodiment.

The variable resistance layer 50 includes the high resistance layer 50x and the low resistance layer 50y.

The high resistance layer 50x is, for example, metal oxide. The high resistance layer 50x is, for example, aluminum oxide, hafnium oxide, zirconium oxide, tantalum oxide, or niobium oxide.

The low resistance layer 50y is, for example, metal oxide. The low resistance layer 50y is, for example, titanium oxide, niobium oxide, tantalum oxide, or tungsten oxide.

The variable resistance layer 50 has the function of storing data in the form of a change in the resistance thereof. The variable resistance layer 50 is characterized, for example, in that application of a predetermined voltage to the variable resistance layer 50 changes the electrical resistance thereof.

Applying the voltage to the variable resistance layer 50 cause the state of the variable resistance layer 50 to change from the high resistance state to the low resistance state, or from the low resistance state to the high resistance state. Applying the voltage to the variable resistance layer 50 cause oxygen ions to move between the high resistance layer 50x and the low resistance layer 50y, and the amount of oxygen deficit or the amount of oxygen vacancy in the low resistance layer 50y changes. The electrical conductivity of the variable resistance layer 50 changes with the amount of oxygen deficit in the low resistance layer 50y. The low resistance layer 50y is what is called a vacancy modulated conductive oxide.

For example, the high resistance state is defined as the data “1”, and the low resistance state is defined as the data “0”. The memory cells MC can each store the 1-bit data, “0” and “1”.

As described above, the storage device 1 according to third embodiment allows a switching element having excellent characteristics, such as high reliability and a small half-select leakage current, to be realized, as in the first embodiment. The third embodiment can therefore realize a storage device including a switching element having excellent characteristics.

### Fourth Embodiment

A storage device 1 according to a fourth embodiment includes memory cells each including a first electrically conductive layer, a second electrically conductive layer, and a memory layer provided between the first and second electrically conductive layers. The memory layer includes at least one first region and at least one second region having a chemical composition different from the chemical composition of the first region. The first region contains a first substance containing a first element selected from the group consisting of zirconium (Zr), yttrium (Y), tantalum (Ta), lanthanum (La), cerium (Ce), titanium (Ti), hafnium (Hf), magnesium (Mg), and aluminum (Al), and a second element selected from the group consisting of oxygen (O), sulfur(S), and selenium (Se). The second region contains a second substance containing the first element and a third element selected from the group consisting of sulfur(S), selenium (Se), and tellurium (Te) and having an atomic number greater than the atomic number of the second element, and a third substance containing a fifth element selected from the group consisting of zinc (Zn), tin (Sn), gallium (Ga), indium (In), bismuth (Bi), magnesium (Mg), and calcium (Ca) and a fourth element selected from the group consisting of sulfur(S), selenium (Se), and tellurium (Te). The first region contains or does not contain the fifth element, and the atomic concentration of the fifth element in the second region is greater than the atomic concentration of the fifth element in the first region.

The storage device 1 according to the fourth embodiment further includes a plurality of first wires and a plurality of second wires that intersect with the plurality of first wires. The memory cell described above is provided in a region where one of the plurality of first wires intersects with one of the plurality of second wires.

The storage device 1 according to the fourth embodiment differs from the storage device 1 according to the first embodiment in that the memory cells each do not include the third electrically conductive layer and the variable resistance layer, but is configured as the memory layer in the same manner as the switching layer in the first embodiment. In the following sections, some descriptions that duplicate the contents of the first embodiment are omitted.

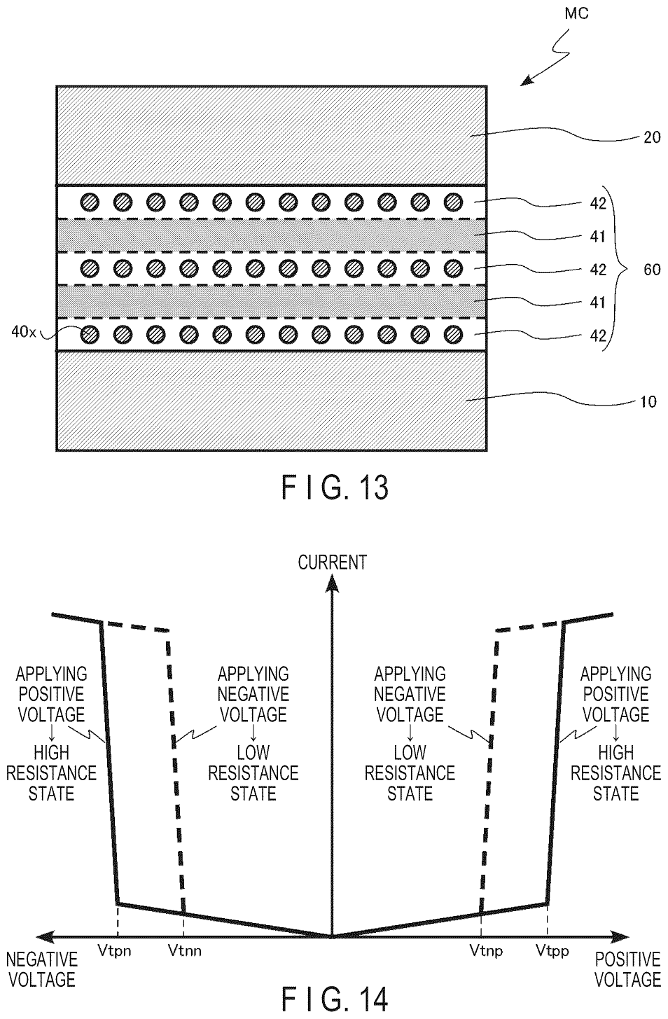

FIG. 13 is a cross-sectional view of each of the memory cells of the storage device 1 according to the fourth embodiment. FIG. 13 shows a cross section, for example, of one memory cell MC indicated by the dotted circle in the memory cell array 100 in FIG. 1.

Each of the memory cells MC of the storage device 1 according to the fourth embodiment includes a lower electrode 10, an upper electrode 20, and a memory layer 60, as shown in FIG. 13.

The lower electrode 10, the memory layer 60, and the upper electrode 20 constitute a memory element of each of the memory cells MC. The memory element of each of the memory cells MC has the switching function and the information storage function.

The memory layer 60 is configured in the same manner as the switching layer 40 in the first embodiment.

The memory layer 60 has a nonlinear current-voltage characteristic that causes the current to steeply rise at a specific threshold voltage. The memory layer 60 is characterized in that application of a predetermined voltage changes the threshold voltage. The memory layer 60 is characterized in that application of a predetermined voltage to the memory layer 60 changes the threshold voltage. The memory layer 60 is further characterized in that the application of the predetermined voltage changes the electrical resistance. In the fourth embodiment, the high resistance state is a state in which the resistance of the memory layer 60 at the read voltage is relatively high. In the fourth embodiment, the low resistance state is a state in which the resistance of the memory layer 60 at the read voltage is relatively low.

The memory layer 60 has the function of suppressing an increase in the half-selected leakage current flowing through the half-selected cells. The memory layer 60 further has the function of storing data in the form of a change in the resistance thereof. The memory layer 60 is a monolayer and realizes the function of the switching layer 40 and the function of the variable resistance layer 50 in the first embodiment.

FIG. 14 is a diagram illustrating the current-voltage characteristic of the memory element in the fourth embodiment. In FIG. 14, the horizontal axis represents the voltage applied to the memory element, and the vertical axis represents the current flowing through the memory element. In FIG. 14, the horizontal axis represents the voltage applied to the upper electrode 20 with respect to the potential at the lower electrode 10. FIG. 14 shows the current-voltage characteristic of the memory layer 60 in the fourth embodiment. FIG. 14 shows the current-voltage characteristic of each of the memory cells MC in the fourth embodiment.

The memory element in the fourth embodiment exhibits different current-voltage characteristics when a predetermined positive voltage is applied to the upper electrode 20 and when a predetermined negative voltage is applied to the upper electrode 20. In FIG. 14, the solid line indicates the current-voltage characteristic provided when the predetermined positive voltage is applied to the upper electrode 20, and the dotted line indicates the current-voltage characteristic provided when the predetermined negative voltage is applied to the upper electrode 20.

When the predetermined positive voltage is applied to the upper electrode 20, the current steeply rises at a first positive-voltage-side threshold voltage Vtpp on the positive voltage side. Furthermore, when the predetermined positive voltage is applied to the upper electrode 20, the current steeply rises at a first negative-voltage-side threshold voltage Vtpn on the negative voltage side.

On the other hand, when the predetermined negative voltage is applied to the upper electrode 20, the current steeply rises at a second positive-voltage-side threshold voltage Vtnp on the positive voltage side. Furthermore, when the predetermined negative voltage is applied to the upper electrode 20, the current steeply rises at a second negative-voltage-side threshold voltage Vtnn on the negative voltage side.

The first positive-voltage-side threshold voltage Vtpp is higher than the second positive-voltage-side threshold voltage Vtnp. The first negative-voltage-side threshold voltage Vtpn is lower than the second negative-voltage-side threshold voltage Vtnn.

The memory element in the fourth embodiment can operate in the high resistance state and the low resistance state both on the positive voltage side and on the negative voltage side. When the predetermined positive voltage is applied to the upper electrode 20, the high resistance state occurs on both the positive and negative voltage sides. On the other hand, when the predetermined negative voltage is applied to the upper electrode 20, the low resistance state occurs on both the positive and negative voltage sides. In the following description, the high resistance state is defined as the data “1”, and the low resistance state is defined as the data “0”. The memory cells MC can each store the 1-bit data, “0” and “1”.

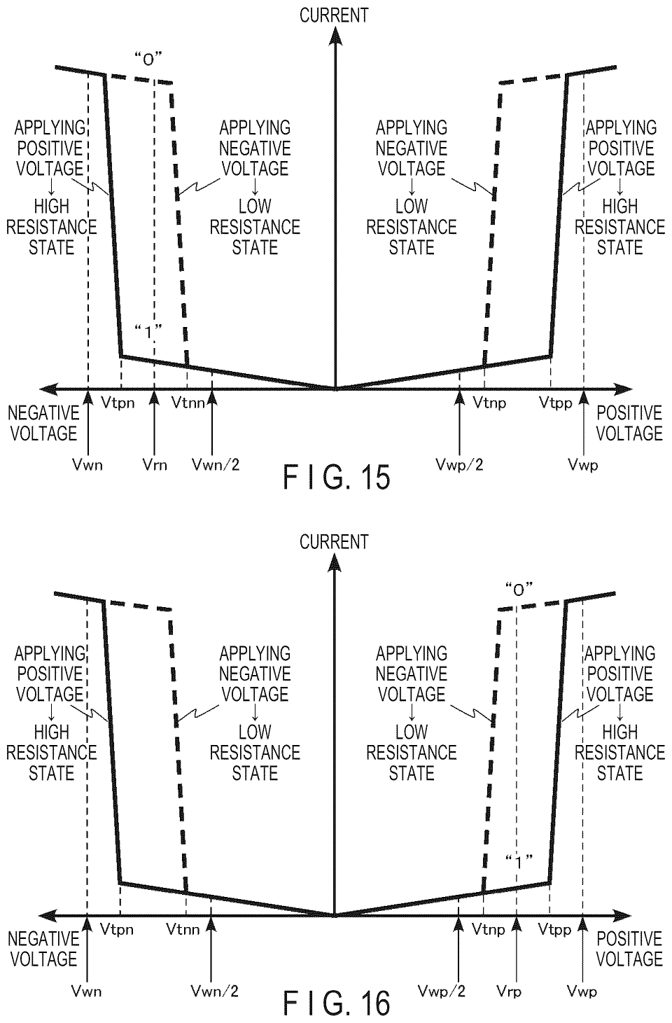

FIG. 15 is a diagram illustrating an example of a first memory operation of the storage device 1 according to the fourth embodiment. FIG. 15 shows a positive write voltage Vwp, a voltage (Vwp/2), which is half the positive write voltage Vwp, a negative write voltage Vwn, a voltage (Vwn/2), which is half the negative write voltage Vwn, and a negative read voltage Vrn in the first memory operation.

In the first operation example, the high resistance state and the low resistance state on the negative voltage side are used for the memory operation. In the first operation example, the negative read voltage Vrn is used as the read voltage.

When the data “1” is written to a selected cell, the positive write voltage Vwp is applied to the upper electrode 20. The positive write voltage Vwp is a voltage higher than the first positive-voltage-side threshold voltage Vtpp. Applying the positive write voltage Vwp to the upper electrode 20 achieves the high resistance state on the negative voltage side, and the data “1” is written to the selected cell.

When the data “0” is written to the selected cell, a negative write voltage Vwn is applied to the upper electrode 20. The negative write voltage Vwn is a voltage lower than the first negative-voltage-side threshold voltage Vtpn. Applying the negative write voltage Vwn to the upper electrode 20 achieves the low resistance state on the negative voltage side, and the data “0” is written to the selected cell.

In the first operation example, when the data “1” is written to the selected cell, and the data stored in the selected cell is the data “0”, the current flows even when the positive write voltage Vwp is lower than the first positive-voltage-side threshold voltage Vtpp, but is higher than the second positive-voltage-side threshold voltage Vtnp. The data “1” may therefore be written. Therefore, for example, setting the positive write voltage Vwp at a voltage between the second positive-voltage-side threshold voltage Vtnp and the first positive-voltage-side threshold voltage Vtpp reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the second positive-voltage-side threshold voltage Vtnp. The voltage Vwn/2 is higher than the second negative-voltage-side threshold voltage Vtnn.

Therefore, even when the half-selected cells operate in the low resistance state, the half-selected leakage current flowing through the half-selected cells can be suppressed. The memory element therefore also functions as a switching element.

To read data from the selected cell, the negative read voltage Vrn is applied to the selected cell. The data in the selected cell can be determined by detecting a change in the current or a change in the potential caused by the difference in the flowing current between the case where the data is “1” and the case where the data is “0”.

Note that in the first operation example, irrespective of the data in the selected cell, the data “1” or the data “0”, applying the negative read voltage Vrn does not destroy the data. In other words, in the first operation example, non-destructive reading can be performed irrespective of the data in the selected cell, the data “1” or the data “0”.

FIG. 16 is a diagram illustrating an example of a second memory operation of the storage device 1 according to the fourth embodiment. FIG. 16 shows the positive write voltage Vwp, the voltage (Vwp/2), which is half the positive write voltage Vwp, the negative write voltage Vwn, the voltage (Vwn/2), which is half the negative write voltage Vwn, and a positive read voltage Vrp in the second memory operation.

In the second operation example, the high resistance state and the low resistance state on the positive voltage side are used for the memory operation. In the second operation example, the positive read voltage Vrp is used as the read voltage.

When the data “1” is written to a selected cell, the positive write voltage Vwp is applied to the upper electrode 20. The positive write voltage Vwp is a voltage higher than the first positive-voltage-side threshold voltage Vtpp. Applying the positive write voltage Vwp to the upper electrode 20 achieves the high resistance state on the positive voltage side, and the data “1” is written to the selected cell.

When the data “0” is written to the selected cell, the negative write voltage Vwn is applied to the upper electrode 20. The negative write voltage Vwn is a voltage lower than the first negative-voltage-side threshold voltage Vtpn. Applying the negative write voltage Vwn to the upper electrode 20 achieves the low resistance state on the positive voltage side, and the data “0” is written to the selected cell.

In the second operation example, when the data “1” is written to the selected cell, and the data stored in the selected cell is the data “0”, the current flows even when the positive write voltage Vwp is lower than the first positive-voltage-side threshold voltage Vtpp, but is higher than the second positive-voltage-side threshold voltage Vtnp. The data “1” may therefore be written. Therefore, for example, setting the positive write voltage Vwp at a voltage between the second positive-voltage-side threshold voltage Vtnp and the first positive-voltage-side threshold voltage Vtpp reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the second positive-voltage-side threshold voltage Vtnp. The voltage Vwn/2 is higher than the second negative-voltage-side threshold voltage Vtnn.

Therefore, even when the half-selected cells operate in the low resistance state, the half-selected leakage current flowing through the half-selected cells can be suppressed. The memory element therefore also functions as a switching element.

To read data from the selected cell, the positive read voltage Vrp is applied to the selected cell. The data in the selected cell can be determined by detecting a change in the current or a change in the potential caused by the difference in the flowing current between the case where the data is “1” and the case where the data is “0”.

Note that in the second operation example, when the data in the selected cell is the data “1”, applying the positive read voltage Vrp does not destroy the data. In other words, in the second operation example, non-destructive reading can be performed when the data in the selected cell is the data “1”.

On the other hand, when the data in the selected cell is the data “0”, applying the positive read voltage Vrp higher than the second positive-voltage-side threshold voltage Vtnp causes the current to flow, so that the data in the selected cell may undesirably change to the data “1”. In other words, in the second operation example, destructive reading may undesirably be performed when the data in the selected cell is the data “0”. Therefore, when the data in the selected cell is the data “0”, it may be necessary to write the data “0” again in order to maintain the data in the selected cell after the data in the selected cell is read.

### (First Variation)

A storage device 1 according to a first variation of the fourth embodiment differs from the storage device 1 according to the fourth embodiment in that the memory element has a different current-voltage characteristic.

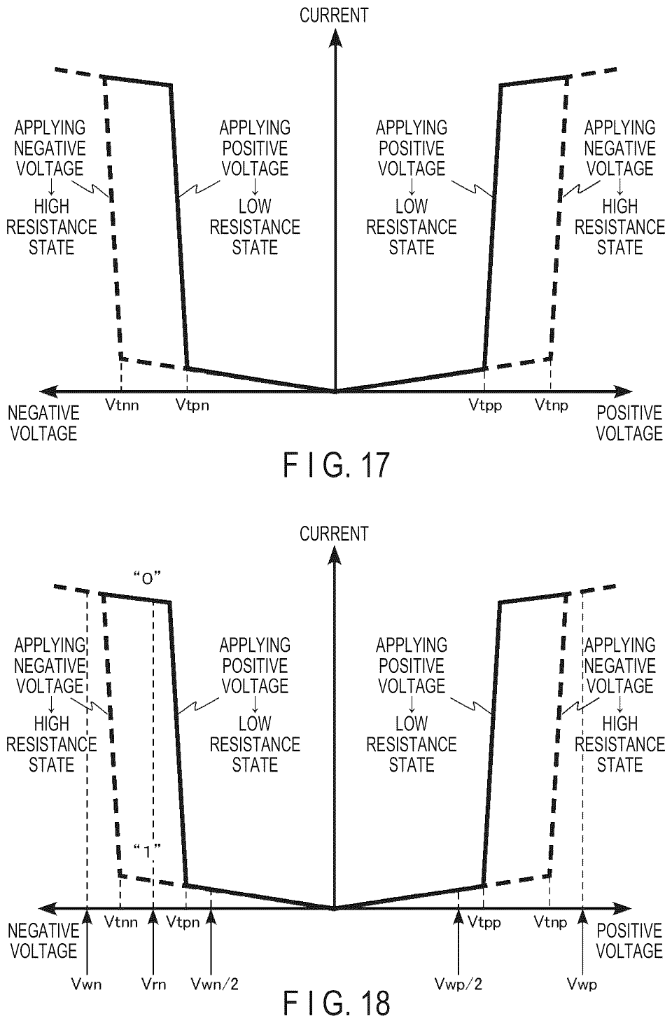

FIG. 17 is a diagram illustrating the current-voltage characteristic of a memory element in the first variation of the fourth embodiment. In FIG. 17, the horizontal axis represents the voltage applied to the memory element, and the vertical axis represents the current flowing through the memory element. In FIG. 17, the horizontal axis represents the voltage applied to the upper electrode 20 with respect to the potential at the lower electrode 10. FIG. 17 shows the current-voltage characteristic of the memory layer 60 in the first variation of the fourth embodiment. FIG. 17 shows the current-voltage characteristic of each of the memory cells MC in the first variation of the fourth embodiment.

The memory element in the first variation of the fourth embodiment exhibits different current-voltage characteristics when a predetermined positive voltage is applied to the upper electrode 20 and when a predetermined negative voltage is applied to the upper electrode 20. In FIG. 17, the solid line indicates the current-voltage characteristic provided when the predetermined positive voltage is applied to the upper electrode 20, and the dotted line indicates the current-voltage characteristic provided when the predetermined negative voltage is applied to the upper electrode 20.

When the predetermined positive voltage is applied to the upper electrode 20, the current steeply rises at the first positive-voltage-side threshold voltage Vtpp on the positive voltage side. Furthermore, when the predetermined positive voltage is applied to the upper electrode 20, the current steeply rises at the first negative-voltage-side threshold voltage Vtpn on the negative voltage side.

On the other hand, when the predetermined negative voltage is applied to the upper electrode 20, the current steeply rises at the second positive-voltage-side threshold voltage Vtnp on the positive voltage side. Furthermore, when the predetermined negative voltage is applied to the upper electrode 20, the current steeply rises at the second negative-voltage-side threshold voltage Vtnn on the negative voltage side.

The first positive-voltage-side threshold voltage Vtpp is lower than the second positive-voltage-side threshold voltage Vtnp. The first negative-voltage-side threshold voltage Vtpn is higher than the second negative-voltage-side threshold voltage Vtnn.

The memory element in the first variation of the fourth embodiment can operate in the high resistance state and the low resistance state both on the positive voltage side and on the negative voltage side. When the predetermined positive voltage is applied to the upper electrode 20, the low resistance state occurs on both the positive and negative voltage sides. On the other hand, when the predetermined negative voltage is applied to the upper electrode 20, the high resistance state occurs on both the positive and negative voltage sides. In the following description, the high resistance state is defined as the data “1”, and the low resistance state is defined as the data “0”. The memory cells MC can each store the 1-bit data, “0” and “1”.

FIG. 18 is a diagram illustrating an example of a third memory operation of the storage device 1 according to the first variation of the fourth embodiment. FIG. 18 shows the positive write voltage Vwp, the voltage (Vwp/2), which is half the positive write voltage Vwp, the negative write voltage Vwn, the voltage (Vwn/2), which is half the negative write voltage Vwn, and the negative read voltage Vrn in the third memory operation.

In the third operation example, the high resistance state and the low resistance state on the negative voltage side are used for the memory operation. In the third operation example, the negative read voltage Vrn is used as the read voltage.

When the data “1” is written to a selected cell, the negative write voltage Vwn is applied to the upper electrode 20. The negative write voltage Vwn is a voltage lower than the second negative-voltage-side threshold voltage Vtnn. Applying the negative write voltage Vwn to the upper electrode 20 achieves the high resistance state on the negative voltage side, and the data “1” is written to the selected cell.

When the data “0” is written to the selected cell, the positive write voltage Vwp is applied to the upper electrode 20. The positive write voltage Vwp is a voltage higher than the second positive-voltage-side threshold voltage Vtnp. Applying the positive write voltage Vwp to the upper electrode 20 achieves the low resistance state on the negative voltage side, and the data “0” is written to the selected cell.

In the third operation example, when the data “1” is written to the selected cell, and the data stored in the selected cell is the data “0”, the current flows even when the negative write voltage Vwn is higher than the second negative-voltage-side threshold voltage Vtnn, but is lower than the first negative-voltage-side threshold voltage Vtpn. The data “1” may therefore be written. Therefore, for example, setting the negative write voltage Vwn at a voltage between the second negative-voltage-side threshold voltage Vtnn and the first negative-voltage-side threshold voltage Vtpn reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the first positive-voltage-side threshold voltage Vtpp. The voltage Vwn/2 is higher than the first negative-voltage-side threshold voltage Vtpn.

Therefore, even when the half-selected cells operate in the low resistance state, the half-selected leakage current flowing through the half-selected cells can be suppressed. The memory element therefore also functions as a switching element.

To read data from the selected cell, the negative read voltage Vrn is applied to the selected cell. The data in the selected cell can be determined by detecting a change in the current or a change in the potential caused by the difference in the flowing current between the case where the data is “1” and the case where the data is “0”.

Note that in the third operation example, when the data in the selected cell is the data “1”, applying the negative read voltage Vrn does not destroy the data. In other words, in the third operation example, non-destructive reading can be performed when the data in the selected cell is the data “1”.

On the other hand, when the data in the selected cell is the data “0”, applying the negative read voltage Vrn lower than the first negative-voltage-side threshold voltage Vtpn causes the current to flow, so that the data in the selected cell may undesirably change to “1”. In other words, in the third operation example, destructive reading may undesirably be performed when the data in the selected cell is the data “0”. Therefore, when the data in the selected cell is the data “0”, it may be necessary to write the data “0” again in order to maintain the data in the selected cell after the data in the selected cell is read.

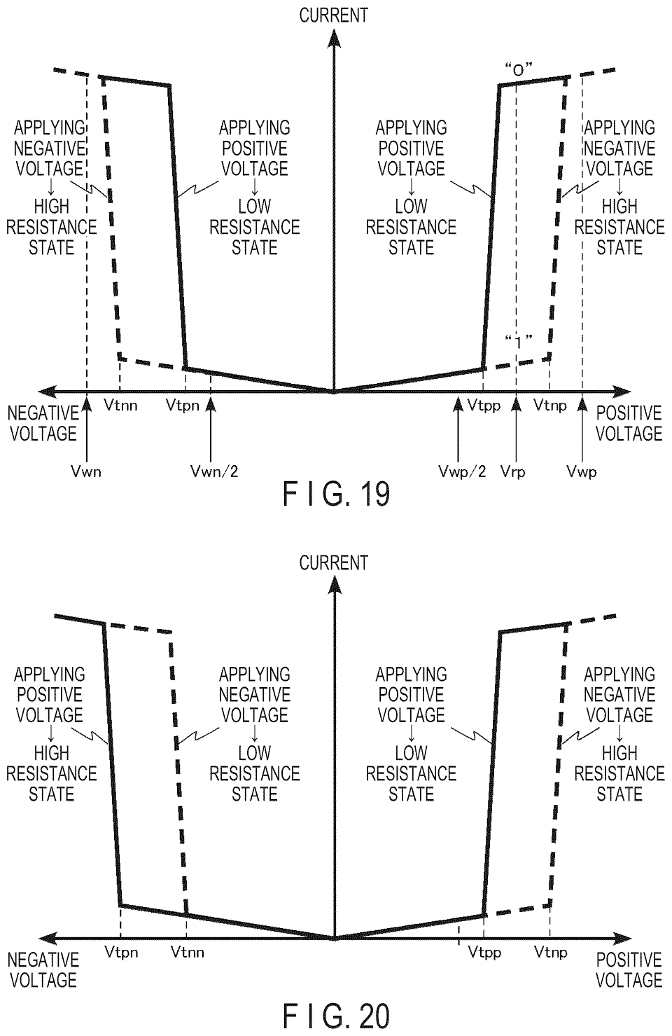

FIG. 19 is a diagram illustrating an example of a fourth memory operation of the storage device 1 according to the first variation of the fourth embodiment. FIG. 19 shows the positive write voltage Vwp, the voltage (Vwp/2), which is half the positive write voltage Vwp, the negative write voltage Vwn, the voltage (Vwn/2), which is half the negative write voltage Vwn, and the positive read voltage Vrp in the fourth memory operation.

In the fourth operation example, the high resistance state and the low resistance state on the positive voltage side are used for the memory operation. In the fourth operation example, the positive read voltage Vrp is used as the read voltage.

When the data “1” is written to a selected cell, the negative write voltage Vwn is applied to the upper electrode 20. The negative write voltage Vwn is a voltage lower than the second negative-voltage-side threshold voltage Vtnn. Applying the negative write voltage Vwn to the upper electrode 20 achieves the high resistance state on the positive voltage side, and the data “1” is written to the selected cell.

When the data “0” is written to the selected cell, the positive write voltage Vwp is applied to the upper electrode 20. The positive write voltage Vwp is a voltage higher than the second positive-voltage-side threshold voltage Vtnp. Applying the positive write voltage Vwp to the upper electrode 20 achieves the low resistance state on the positive voltage side, and the data “0” is written to the selected cell.

In the fourth operation example, when the data “1” is written to the selected cell, and the data stored in the selected cell is the data “0”, the current flows even when the negative write voltage Vwn is higher than the second negative-voltage-side threshold voltage Vtnn, but is lower than the first negative-voltage-side threshold voltage Vtpn. The data “1” may therefore be written. Therefore, for example, setting the negative write voltage Vwn at a voltage between the second negative-voltage-side threshold voltage Vtnn and the first negative-voltage-side threshold voltage Vtpn reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the first positive-voltage-side threshold voltage Vtpp. The voltage Vwn/2 is higher than the first negative-voltage-side threshold voltage Vtpn.

Therefore, even when the half-selected cells operate in the low resistance state, the half-selected leakage current flowing through the half-selected cells can be suppressed. The memory element therefore also functions as a switching element.

To read data from the selected cell, the positive read voltage Vrp is applied to the selected cell. The data in the selected cell can be determined by detecting a change in the current or a change in the potential caused by the difference in the flowing current between the case where the data is “1” and the case where the data is “0”.

Note that in the fourth operation example, irrespective of the data in the selected cell, the data “1” or the data “0”, applying the positive read voltage Vrp does not destroy the data. In other words, in the fourth operation example, non-destructive reading can be performed irrespective of the data in the selected cell, the data “1” or the data “0”.

### (Second Variation)

A storage device 1 according to a second variation of the fourth embodiment differs from the storage device 1 according to the fourth embodiment in that the memory element has a different current-voltage characteristic.

FIG. 20 is a diagram illustrating the current-voltage characteristic of the memory element in the second variation of the fourth embodiment. In FIG. 20, the horizontal axis represents the voltage applied to the memory element, and the vertical axis represents the current flowing through the memory element. In FIG. 20, the horizontal axis represents the voltage applied to the upper electrode 20 with respect to the potential at the lower electrode 10. FIG. 20 shows the current-voltage characteristic of the memory layer 60 in the second variation of the fourth embodiment. FIG. 20 shows the current-voltage characteristic of each of the memory cells MC in the second variation of the fourth embodiment.

The memory element in the second variation of the fourth embodiment exhibits different current-voltage characteristics when a predetermined positive voltage is applied to the upper electrode 20 and when a predetermined negative voltage is applied to the upper electrode 20. In FIG. 20, the solid line indicates the current-voltage characteristic provided when the predetermined positive voltage is applied to the upper electrode 20, and the dotted line indicates the current-voltage characteristic provided when the predetermined negative voltage is applied to the upper electrode 20.

When the predetermined positive voltage is applied to the upper electrode 20, the current steeply rises at the first positive-voltage-side threshold voltage Vtpp on the positive voltage side. Furthermore, when the predetermined positive voltage is applied to the upper electrode 20, the current steeply rises at the first negative-voltage-side threshold voltage Vtpn on the negative voltage side.

On the other hand, when the predetermined negative voltage is applied to the upper electrode 20, the current steeply rises at the second positive-voltage-side threshold voltage Vtnp on the positive voltage side. Furthermore, when the predetermined negative voltage is applied to the upper electrode 20, the current steeply rises at the second negative-voltage-side threshold voltage Vtnn on the negative voltage side.

The first positive-voltage-side threshold voltage Vtpp is lower than the second positive-voltage-side threshold voltage Vtnp. The first negative-voltage-side threshold voltage Vtpn is lower than the second negative-voltage-side threshold voltage Vtnn.

The memory element in the second variation of the fourth embodiment can operate in the high resistance state and the low resistance state both on the positive voltage side and on the negative voltage side. When the predetermined positive voltage is applied to the upper electrode 20, the low resistance state occurs on the positive voltage side, and the high resistance state occurs on the negative voltage side. On the other hand, when the predetermined negative voltage is applied to the upper electrode 20, the high resistance state occurs on the positive voltage side, and the low resistance state occurs on the negative voltage side. In the following description, the high resistance state is defined as the data “1”, and the low resistance state is defined as the data “0”. The memory cells MC can each store the 1-bit data, “0” and “1”.

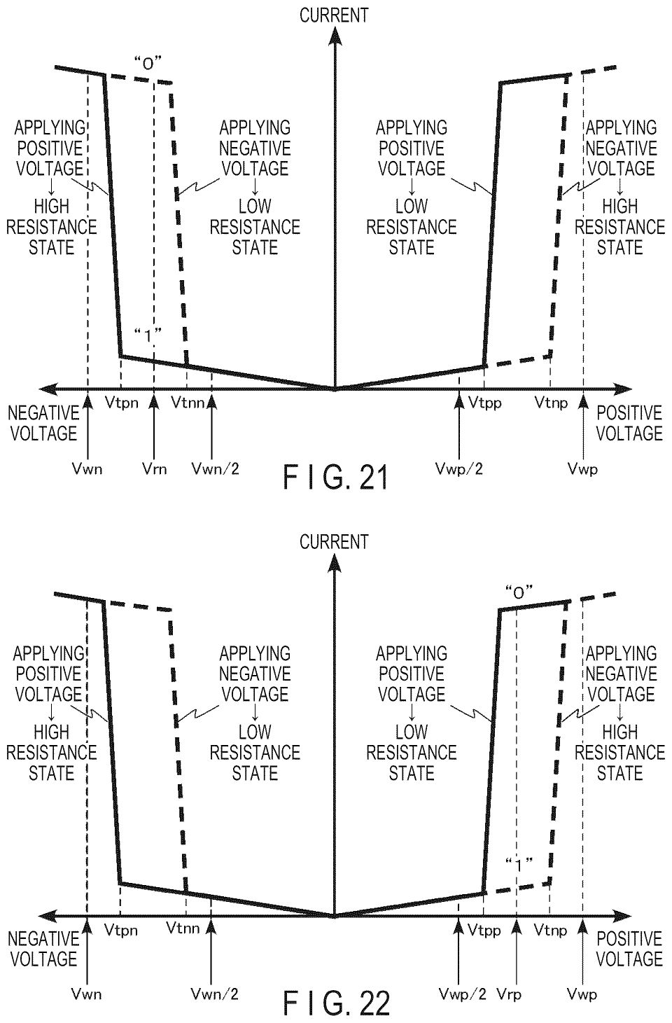

FIG. 21 is a diagram illustrating an example of a fifth memory operation of the storage device 1 according to the second variation of the fourth embodiment. FIG. 21 shows the positive write voltage Vwp, the voltage (Vwp/2), which is half the positive write voltage Vwp, the negative write voltage Vwn, the voltage (Vwn/2), which is half the negative write voltage Vwn, and the negative read voltage Vrn in the fifth memory operation.

In the fifth operation example, the high resistance state and the low resistance state on the negative voltage side are used for the memory operation. In the fifth operation example, the negative read voltage Vrn is used as the read voltage.

When the data “1” is written to a selected cell, the positive write voltage Vwp is applied to the upper electrode 20. The positive write voltage Vwp is a voltage higher than the second positive-voltage-side threshold voltage Vtnp. Applying the positive write voltage Vwp to the upper electrode 20 achieves the high resistance state on the negative voltage side, and the data “1” is written to the selected cell.

When the data “0” is written to the selected cell, the negative write voltage Vwn is applied to the upper electrode 20. The negative write voltage Vwn is a voltage lower than the first negative-voltage-side threshold voltage Vtpn. Applying the negative write voltage Vwn to the upper electrode 20 achieves the low resistance state on the negative voltage side, and the data “0” is written to the selected cell.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the first positive-voltage-side threshold voltage Vtpp. The voltage Vwn/2 is higher than the second negative-voltage-side threshold voltage Vtnn.

Therefore, even when the half-selected cells operate in the low resistance state, the half-selected leakage current flowing through the half-selected cells can be suppressed. The memory element therefore also functions as a switching element.

To read data from the selected cell, the negative read voltage Vrn is applied to the selected cell. The data in the selected cell can be determined by detecting a change in the current or a change in the potential caused by the difference in the flowing current between the case where the data is “1” and the case where the data is “0”.

Note that in the fifth operation example, irrespective of the data in the selected cell, the data “1” or the data “0”, applying the negative read voltage Vrn does not destroy the data. In other words, in the fifth operation example, non-destructive reading can be performed irrespective of the data in the selected cell, the data “1” or the data “0”.

FIG. 22 is a diagram illustrating an example of a sixth memory operation of the storage device 1 according to the second variation of the fourth embodiment. FIG. 22 shows the positive write voltage Vwp, the voltage (Vwp/2), which is half the positive write voltage Vwp, the negative write voltage Vwn, the voltage (Vwn/2), which is half the negative write voltage Vwn, and the positive read voltage Vrp in the sixth memory operation.

In the sixth operation example, the high resistance state and the low resistance state on the positive voltage side are used for the memory operation. In the sixth operation example, the positive read voltage Vrp is used as the read voltage.

When the data “1” is written to a selected cell, the negative write voltage Vwn is applied to the upper electrode 20. The negative write voltage Vwn is a voltage lower than the first negative-voltage-side threshold voltage Vtpn. Applying the negative write voltage Vwn to the upper electrode 20 achieves the high resistance state on the positive voltage side, and the data “1” is written to the selected cell.

When the data “0” is written to the selected cell, the positive write voltage Vwp is applied to the upper electrode 20. The positive write voltage Vwp is a voltage higher than the second positive-voltage-side threshold voltage Vtnp. Applying the positive write voltage Vwp to the upper electrode 20 achieves the low resistance state on the positive voltage side, and the data “O” is written to the selected cell.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the first positive-voltage-side threshold voltage Vtpp. The voltage Vwn/2 is higher than the second negative-voltage-side threshold voltage Vtnn.

Therefore, even when the half-selected cells operate in the low resistance state, the half-selected leakage current flowing through the half-selected cells can be suppressed. The memory element therefore also functions as a switching element.

To read data from the selected cell, the positive read voltage Vrp is applied to the selected cell. The data in the selected cell can be determined by detecting a change in the current or a change in the potential caused by the difference in the flowing current between the case where the data is “1” and the case where the data is “0”.

Note that in the sixth operation example, irrespective of the data in the selected cell, the data “1” or the data “0”, applying the positive read voltage Vrp does not destroy the data. In other words, in the sixth operation example, non-destructive reading can be performed irrespective of the data in the selected cell, the data “1” or the data “0”.

### (Third Variation)

A storage device 1 according to a third variation of the fourth embodiment differs from the storage device 1 according to the fourth embodiment in that the memory element has a different current-voltage characteristic.

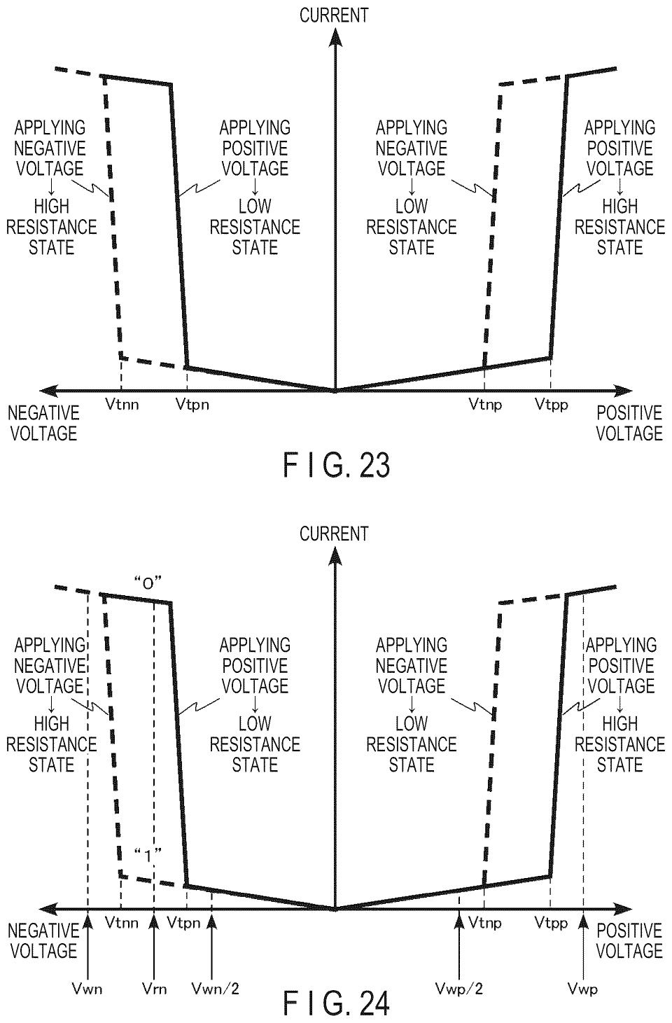

FIG. 23 is a diagram illustrating the current-voltage characteristic of the memory element in the third variation of the fourth embodiment. In FIG. 23, the horizontal axis represents the voltage applied to the memory element, and the vertical axis represents the current flowing through the memory element. In FIG. 23, the horizontal axis represents the voltage applied to the upper electrode 20 with respect to the potential at the lower electrode 10. FIG. 23 shows the current-voltage characteristic of the memory layer 60 in the third variation of the fourth embodiment. FIG. 23 shows the current-voltage characteristic of each of the memory cells MC in the third variation of the fourth embodiment.

The memory element in the third variation of the fourth embodiment exhibits different current-voltage characteristics when a predetermined positive voltage is to the upper electrode 20 a applied and when predetermined negative voltage is applied to the upper electrode 20. In FIG. 23, the solid line indicates the current-voltage characteristic provided when the predetermined positive voltage is applied to the upper electrode 20, and the dotted line indicates the current-voltage characteristic provided when the predetermined negative voltage is applied to the upper electrode 20.

When the predetermined positive voltage is applied to the upper electrode 20, the current steeply rises at the first positive-voltage-side threshold voltage Vtpp on the positive voltage side. Furthermore, when the predetermined positive voltage is applied to the upper electrode 20, the current steeply rises at the first negative-voltage-side threshold voltage Vtpn on the negative voltage side.

On the other hand, when the predetermined negative voltage is applied to the upper electrode 20, the current steeply rises at the second positive-voltage-side threshold voltage Vtnp on the positive voltage side. Furthermore, when the predetermined negative voltage is applied to the upper electrode 20, the current steeply rises at the second negative-voltage-side threshold voltage Vtnn on the negative voltage side.

The first positive-voltage-side threshold voltage Vtpp is higher than the second positive-voltage-side threshold voltage Vtnp. The first negative-voltage-side threshold voltage Vtpn is higher than the second negative-voltage-side threshold voltage Vtnn.

The memory element in the third variation of the fourth embodiment can operate in the high resistance state and the low resistance state both on the positive voltage side and on the negative voltage side. When the predetermined positive voltage is applied to the upper electrode 20, the high resistance state occurs on the positive voltage side, and the low resistance state occurs on the negative voltage side. On the other hand, when the predetermined negative voltage is applied to the upper electrode 20, the low resistance state occurs on the positive voltage side, and the high resistance state occurs on the negative voltage side. In the following description, the high resistance state is defined as the data “1”, and the low resistance state is defined as the data “0”. The memory cells MC can each store the 1-bit data, “0” and “1”.

FIG. 24 is a diagram illustrating an example of a seventh memory operation of the storage device 1 according to the third variation of the fourth embodiment. FIG. 24 shows the positive write voltage Vwp, the voltage (Vwp/2), which is half the positive write voltage Vwp, the negative write voltage Vwn, the voltage (Vwn/2), which is half the negative write voltage Vwn, and the negative read voltage Vrn in the seventh memory operation.

In the seventh operation example, the high resistance state and the low resistance state on the negative voltage side are used for the memory operation. In the seventh operation example, the negative read voltage Vrn is used as the read voltage.

When the data “1” is written to a selected cell, the negative write voltage Vwn is applied to the upper electrode 20. The negative write voltage Vwn is a voltage lower than the second negative-voltage-side threshold voltage Vtnn. Applying the negative write voltage Vwn to the upper electrode 20 achieves the high resistance state on the negative voltage side, and the data “1” is written to the selected cell.

When the data “0” is written to the selected cell, the positive write voltage Vwp is applied to the upper electrode 20. The positive write voltage Vwp is a voltage higher than the first positive-voltage-side threshold voltage Vtpp. Applying the positive write voltage Vwp to the upper electrode 20 achieves the low resistance state on the negative voltage side, and the data “0” is written to the selected cell.

In the seventh operation example, when the data “1” is written to the selected cell, and the data stored in the selected cell is the data “0”, the current flows even when the negative write voltage Vwn is higher than the second negative-voltage-side threshold voltage Vtnn, but is lower than the first negative-voltage-side threshold voltage Vtpn. The data “1” may therefore be written. Therefore, for example, setting the negative write voltage Vwn at a voltage between the second negative-voltage-side threshold voltage Vtnn and the first negative-voltage-side threshold voltage Vtpn reduces the power consumed by the storage device 1 and increases its reliability.

Furthermore, in the seventh operation example, when the data “0” is written to the selected cell, and the data stored in the selected cell is the data “1”, the current flows even when the positive write voltage Vwp is lower than the first positive-voltage-side threshold voltage Vtpp, but is higher than the second positive-voltage-side threshold voltage Vtnp. The data “0” may therefore be written. Therefore, for example, setting the positive write voltage Vwp at a voltage between the second positive-voltage-side threshold voltage Vtnp and the first positive-voltage-side threshold voltage Vtpp reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the second positive-voltage-side threshold voltage Vtnp. The voltage Vwn/2 is higher than the first negative-voltage-side threshold voltage Vtpn.

Therefore, even when the half-selected cells operate in the low resistance state, the half-selected leakage current flowing through the half-selected cells can be suppressed. The memory element therefore also functions as a switching element.

To read data from the selected cell, the negative read voltage Vrn is applied to the selected cell. The data in the selected cell can be determined by detecting a change in the current or a change in the potential caused by the difference in the flowing current between the case where the data is “1” and the case where the data is “0”.

Note that in the seventh operation example, when the data in the selected cell is the data “1”, applying the negative read voltage Vrn does not destroy the data. In other words, in the seventh operation example, non-destructive reading can be performed when the data in the selected cell is the data “1”.

On the other hand, when the data in the selected cell is the data “0”, applying the negative read voltage Vrn lower than the first negative-voltage-side threshold voltage Vtpn causes the current to flow, so that the data in the selected cell may undesirably change to “1”. In other words, in the seventh operation example, destructive reading may undesirably be performed when the data in the selected cell is the data “0”. Therefore, when the data in the selected cell is the data “0”, it may be necessary to write the data “0” again in order to maintain the data in the selected cell after the data in the selected cell is read.

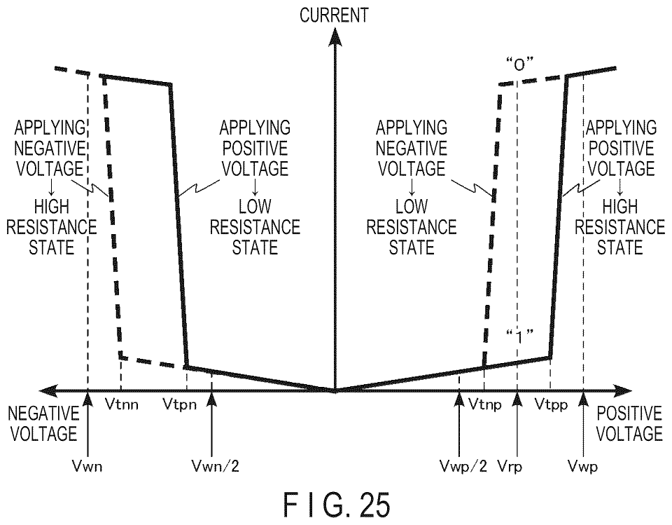

FIG. 25 is a diagram illustrating an example of an eighth memory operation of the storage device 1 according to the third variation of the fourth embodiment. FIG. 25 shows the positive write voltage Vwp, the voltage (Vwp/2), which is half the positive write voltage Vwp, the negative write voltage Vwn, the voltage (Vwn/2), which is half the negative write voltage Vwn, and the positive read voltage Vrp in the eighth memory operation.

In the eighth operation example, the high resistance state and the low resistance state on the positive voltage side are used for the memory operation. In the eighth operation example, the positive read voltage Vrp is used as the read voltage.

When the data “1” is written to a selected cell, the positive write voltage Vwp is applied to the upper electrode 20. The positive write voltage Vwp is a voltage higher than the first positive-voltage-side threshold voltage Vtpp. Applying the positive write voltage Vwp to the upper electrode 20 achieves the high resistance state on the positive voltage side, and the data “1” is written to the selected cell.

When the data “0” is written to the selected cell, the negative write voltage Vwn is applied to the upper electrode 20. The negative write voltage Vwn is a voltage lower than the second negative-voltage-side threshold voltage Vtnn. Applying the negative write voltage Vwn to the upper electrode 20 achieves the low resistance state on the positive voltage side, and the data “0” is written to the selected cell.

In the eighth operation example, when the data “1” is written to the selected cell, and the data stored in the selected cell is the data “0”, the current flows even when the positive write voltage Vwp is lower than the first positive-voltage-side threshold voltage Vtpp, but is higher than the second positive-voltage-side threshold voltage Vtnp. The data “1” may therefore be written. Therefore, for example, setting the positive write voltage Vwp at a voltage between the second positive-voltage-side threshold voltage Vtnp and the first positive-voltage-side threshold voltage Vtpp reduces the power consumed by the storage device 1 and increases its reliability.

In the eighth operation example, when the data “0” is written to the selected cell, and the data stored in the selected cell is the data “1”, the current flows even when the negative write voltage Vwn is higher than the second negative-voltage-side threshold voltage Vtnn, but is lower than the first negative-voltage-side threshold voltage Vtpn. The data “0” may therefore be written. Therefore, for example, setting the negative write voltage Vwn at a voltage between the second negative-voltage-side threshold voltage Vtnn and the first negative-voltage-side threshold voltage Vtpn reduces the power consumed by the storage device 1 and increases its reliability.

Note that when the positive write voltage Vwp is applied to the selected cell, the voltage Vwp/2 is applied to the half-selected cells. When the negative write voltage Vwn is applied to the selected cell, the voltage Vwn/2 is applied to the half-selected cells. The voltage Vwp/2 is lower than the second positive-voltage-side threshold voltage Vtnp. The voltage Vwn/2 is higher than the first negative-voltage-side threshold voltage Vtpn.

Therefore, even when the half-selected cells operate in the low resistance state, the half-selected leakage current flowing through the half-selected cells can be suppressed. The memory element therefore also functions as a switching element.

To read data from the selected cell, the positive read voltage Vrp is applied to the selected cell. The data in the selected cell can be determined by detecting a change in the current or a change in the potential caused by the difference in the flowing current between the case where the data is “1” and the case where the data is “0”.

Note that in the eighth operation example, when the data in the selected cell is the data “1”, applying the positive read voltage Vrp does not destroy the data. In other words, in the eighth operation example, non-destructive reading can be performed when the data in the selected cell is the data “1”.

On the other hand, when the data in the selected cell is the data “0”, applying the positive read voltage Vrp higher than the second positive-voltage-side threshold voltage Vtnp causes the current to flow, so that the data in the selected cell may undesirably change to the data “1”. In other words, in the eighth operation example, destructive may reading undesirably be performed when the data in the selected cell is the data “0”. Therefore, when the data in the selected cell is the data “0”, it may be necessary to write the data “0” again in order to maintain the data in the selected cell after the data in the selected cell is read.

In the storage device 1 according to the fourth embodiment and the variations thereof, the memory element of each of the memory cells MC has the switching function and the information storage function. The memory layer 60 is a monolayer and realizes the function of the switching layer 40 and the function of the variable resistance layer 50 in the first embodiment. Since the memory layer 60 in the fourth embodiment is a monolayer and has the switching function and the memory function, the memory cells MC can each have an extremely simple structure.

Furthermore, the memory layer 60 of the storage device 1 according to the fourth embodiment and the variations thereof is configured in the same manner as the switching layer 40 in the first embodiment. The fourth embodiment and the variations thereof can therefore realize a storage device including a switching element having excellent characteristics, as the first embodiment.

Note that the plurality of current-voltage characteristics of the memory elements shown in the fourth embodiment and the variations thereof can each be realized, for example, by employing the memory layer 60 having an appropriate chemical composition.

The first and second embodiments have been described with reference to a magneto-resistive memory used as an example of a two-terminal storage device, and the third embodiment has been described with reference to a variable resistance memory used as an example of a two-terminal storage device. However, embodiments of this disclosure are also applicable to other storage devices. For example, the present invention is applicable to a phase change memory (PCM) or ferroelectric random access memory (FeRAM).

The fourth embodiment has been described with reference to the case where the memory layer is configured in the same manner as the switching layer in the first embodiment as an example, and the memory layer may be configured in the same manner as the switching layer in the fourth variation of the first embodiment or the switching layer in the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a plurality of memory cells each including:
a first conductive layer,
a second conductive layer,
a third conductive layer between the first and second conductive layers,
a switching layer between the first and third conductive layers, and
a variable resistance layer between the second and third conductive layers, wherein
the switching layer includes at least one first region and at least one second region,
the first region includes at least:
a first element selected from a group consisting of zirconium, yttrium, tantalum, lanthanum, cerium, titanium, hafnium, magnesium, and aluminum, and
a second element selected from a group consisting of oxygen, sulfur, and selenium,
the second region includes at least:
the first element,
a third element selected from a group consisting of sulfur, selenium, and tellurium, an atomic number of the third element being greater than an atomic number of the second element, and
a fourth element selected from a group consisting of sulfur, selenium, and tellurium, and
an atomic concentration of a fifth element in the second region is higher than an atomic concentration of the fifth element in the first region, the fifth element being selected from a group consisting of zinc, tin, gallium, indium, bismuth, magnesium, and calcium.

2. The storage device according to claim 1, wherein the atomic concentration of the fifth element in the first region is zero.

3. The storage device according to claim 1, wherein the first and second regions are alternately disposed along a first direction from the first conductive layer toward the second conductive layer.

4. The storage device according to claim 1, wherein the first element is zirconium.

5. The storage device according to claim 1, wherein the fourth element is tellurium, and the fifth element is zinc.

6. The storage device according to claim 1, wherein the first region includes a compound of the first and second elements, and
the second region includes a compound of the first and third elements and a compound of the fourth and fifth elements.

7. The storage device according to claim 1, wherein the variable resistance layer includes a magnetic tunnel junction.

8. The storage device according to claim 1, wherein
a resistance value of the variable resistance layer changes when a predetermined voltage is applied thereto, and
a current that flows through the switching layer changes non-linearly when a voltage greater than or equal to a threshold voltage is applied thereto.

9. The storage device according to claim 1, further comprising:
a plurality of first wires; and
a plurality of second wires that intersect with the first wires, wherein
the memory cells are provided at intersections of the first and second wires.

10. A storage device comprising:
a plurality of memory cells each including:
a first conductive layer,
a second conductive layer,
a third conductive layer between the first and second conductive layers,
a switching layer between the first and third conductive layers, and
a variable resistance layer between the second and third conductive layers, wherein
the switching layer includes:
at least one first region including a first material, and
at least one second region including a second material and a third material, the third material including zinc and at least one element selected from a group consisting of sulfur, selenium, and tellurium,
a combination of the first and second materials is selected from a group consisting of:
a first combination in which the first material includes silicon and oxygen, and the second material includes oxygen and at least one element selected from a group consisting of zirconium, hafnium, titanium, and aluminum,
a second combination in which the first material includes silicon and oxygen, and the second material includes nitrogen and at least one element selected from a group consisting of silicon, aluminum, and gallium,
a third combination in which the first material includes silicon and nitrogen, and the second material includes oxygen and at least one element selected from a group consisting of zirconium, hafnium, titanium, and aluminum,
a fourth combination in which the first material includes silicon and nitrogen, and the second material includes aluminum and nitrogen,
a fifth combination in which the first material includes aluminum and nitrogen, and the second material includes oxygen and at least one element selected from a group consisting of zirconium and hafnium, and
a sixth combination in which the first material includes zirconium and oxygen, and the second material includes hafnium and oxygen, and
an atomic concentration of zinc in the second region is higher than an atomic concentration of zinc in the first region.

11. The storage device according to claim 10, wherein the atomic concentration of zinc in the first region is zero.

12. The storage device according to claim 10, wherein the first and second regions are alternately disposed along a first direction from the first conductive layer toward the second conductive layer.

13. A storage device comprising:
a plurality of memory cells each including:
a first conductive layer,
a second conductive layer,
a third conductive layer between the first and second conductive layers,
a switching layer between the first and third conductive layers, and
a variable resistance layer between the second and third conductive layers, wherein
the switching layer includes at least one first region and at least one second region,
the first region includes a first material,
the second region includes a second material and a third material, wherein
a band gap of the second material is narrower than a band gap of the first material, and
the third material includes a first element selected from a group consisting of sulfur, selenium, and tellurium, and
an atomic concentration of a second element in the second region is higher than an atomic concentration of the second element in the first region, the second element being selected from a group consisting of zinc, tin, gallium, indium, bismuth, magnesium, and calcium.

14. The storage device according to claim 13, wherein the first and second regions are alternately disposed along a first direction from the first conductive layer toward the second conductive layer.

15. The storage device according to claim 13, wherein each of the first and second materials includes oxygen or nitrogen.

16. The storage device according to claim 13, wherein an amount of electric charge of the third material in a case where the third material is present in the first material is greater than an amount of electric charge of the third material in a case where the third material is present in the second material.

17. A storage device comprising:
a plurality of memory cells each including:
a first conductive layer,
a second conductive layer, and
a memory layer between the first and second conductive layers, wherein
the memory layer includes at least one first region and at least one second region,
the first region includes at least:
a first element selected from a group consisting of zirconium, yttrium, tantalum, lanthanum, cerium, titanium, hafnium, magnesium, and aluminum, and
a second element selected from a group consisting of oxygen, sulfur, and selenium,
the second region includes at least:
the first element,
a third element selected from a group consisting of sulfur, selenium, and tellurium, an atomic number of the third element being greater than an atomic number of the second element, and
a fourth element selected from a group consisting of sulfur, selenium, and tellurium, and
an atomic concentration of a fifth element in the second region is higher than an atomic concentration of the fifth element in the first region, the fifth element being selected from a group consisting of zinc, tin, gallium, indium, bismuth, magnesium, and calcium.

18. The storage device according to claim 17, wherein
a current that flows through the memory layer changes non-linearly when a voltage greater than or equal to a threshold voltage is applied thereto, and
the threshold voltage changes when a predetermined voltage is applied to the memory layer.

19. A storage device comprising:
a plurality of memory cells each including:
a first conductive layer,
a second conductive layer, and
a memory layer between the first and second conductive layers, wherein
the memory layer includes at least one first region including a first material and at least one second region including a second material and a third material,
the third material includes zinc and at least one element selected from a group consisting of sulfur, selenium, and tellurium,
a combination of the first and second materials is selected from a group consisting of:
a first combination in which the first material includes silicon and oxygen, and the second material includes oxygen and at least one element selected from a group consisting of zirconium, hafnium, titanium, and aluminum,
a second combination in which the first material includes silicon and oxygen, and the second material includes nitrogen and at least one element selected from a group consisting of silicon, aluminum, and gallium,
a third combination in which the first material includes silicon and nitrogen, and the second material includes oxygen and at least one element selected from a group consisting of zirconium, hafnium, titanium, and aluminum,
a fourth combination in which the first material includes silicon and nitrogen, and the second material includes aluminum and nitrogen,
a fifth combination in which the first material includes aluminum and nitrogen, and the second material includes oxygen and at least one element selected from a group consisting of zirconium and hafnium, and
a sixth combination in which the first material includes zirconium and oxygen, and the second material includes hafnium and oxygen, and
an atomic concentration of zinc in the second region is higher than an atomic concentration of zinc in the first region.

20. The storage device according to claim 19, wherein
a current that flows through the memory layer changes non-linearly when a voltage greater than or equal to a threshold voltage is applied thereto, and
the threshold voltage changes when a predetermined voltage is applied to the memory layer.

21. A storage device comprising:
a plurality of memory cells each including:
a first conductive layer,
a second conductive layer, and
a memory layer between the first and second conductive layers, wherein
the memory layer includes at least one first region and at least one second region,
the first region includes a first material,
the second region includes a second material and a third material, wherein
a band gap of the second material is narrower than a band gap of the first material, and
the third material includes a first element selected from a group consisting of sulfur, selenium, and tellurium, and
an atomic concentration of a second element in the second region is higher than an atomic concentration of the second element in the first region, the second element being selected from a group consisting of zinc, tin, gallium, indium, bismuth, magnesium, and calcium.

22. The storage device according to claim 21, wherein
a current that flows through the memory layer changes non-linearly when a voltage greater than or equal to a threshold voltage is applied thereto, and
the threshold voltage changes when a predetermined voltage is applied to the memory layer.
